(19) United States
(12) Patent Application Publication
(10) Pub. No.: US 2014/0017819 A1
(43) Pub. Date: Jan. 16, 2014

(54) SEMICONDUCTOR DEVICE AND METHOD OF MANUFACTURING THE SAME

(71) Applicant: FUJITSU SEMICONDUCTOR LIMITED, Yokohama-shi (JP)

(72) Inventors: Hiroki SUGAWARA, Kawasaki (JP); Kouichi NAGAI, Kawasaki (JP)

(73) Assignee: FUJITSU SEMICONDUCTOR LIMITED, Yokohama-shi (JP)

(21) Appl. No.: 14/030,567

(22) Filed: Sep. 18, 2013

Related U.S. Application Data
(62) Division of application No. 12/147,899, filed on Jun. 27, 2008.

(30) Foreign Application Priority Data
Dec. 28, 2005 (JP) PCT/JP2005/024059

(51) Int. Cl. H01L 49/02

(52) U.S. Cl. CPC H01L 28/57
USPC 438/3

(57) ABSTRACT

A ferroelectric capacitor is formed above a semiconductor substrate (1), and thereafter, wirings (24a) are formed. A barrier film (25) covering the wirings (24a) is formed. A silicon oxide film (26) embedding gaps between the adjacent wirings (24a) is formed. The silicon oxide film (26) is polished until a surface of the barrier film (25) is exposed by a CMP method. A barrier film (27) is formed on the barrier film (25) and the silicon oxide film (26). Aluminum oxide films are formed as the barrier films (25, 27).

### CROSS-REFERENCE TO RELATED APPLICATION

This application is a divisional of application Ser. No. 12/147,899, filed Jun. 27, 2008, which is a continuation application of International Application PCT/JP2005/024059 filed on Dec. 28, 2005 and designated the U.S., the entire contents of which are incorporated herein by reference.

### TECHNICAL FIELD

The embodiments discussed herein are directed to a semiconductor device including a ferroelectric capacitor and suitable for a nonvolatile memory, and a manufacturing method thereof.

### BACKGROUND ART

In recent years, a development of a ferroelectric memory (FeRAM) holding information on a ferroelectric capacitor by using a polarization inversion of a ferroelectric substance is in progress. The ferroelectric memory is a nonvolatile memory, in which the held information is not lost even if power supply is shut off, and it attracts attention in particular because it is possible to realize a high integration, a high-speed driving, a high durability and a low power consumption.

As a ferroelectric film constituting the ferroelectric capacitor, ferroelectric oxide films having a perovskite crystal structure such as a PZT (Pb(Zr, Ti)O₃) film and an SBT (SrBi₂Ta₂O₉) film, whose amount of remanent polarization are large, are mainly used. The amount of remanent polarization of the PZT film is approximately 10 μC/cm² to 30 μC/cm². However, properties of the ferroelectric film (the amount of remanent polarization, a dielectric constant, and so on) are easy to deteriorate by moisture. In the ferroelectric memory, a silicon oxide film or the like having a high affinity with moisture is used as interlayer insulating films. Besides, in a manufacturing process of the ferroelectric memory, a heat treatment is performed for interlayer insulating films and metal wirings. The moisture penetrating from outside and existing in the interlayer insulating films is decomposed to hydrogen and oxygen at the time of the heat treatment, and hydrogen reacts with oxygen atoms in the ferroelectric film. As a result of this, oxygen deficiency occurs in the ferroelectric film, crystallinity is lowered and the properties deteriorate. Besides, the similar phenomenon may occur by using the ferroelectric memory for a long time.

The deterioration of properties in accordance with the penetration of moisture and the diffusion of hydrogen as stated above may occur not only in the ferroelectric capacitor but also in other elements such as a transistor in a semiconductor device.

An aluminum oxide film is therefore formed conventionally above the ferroelectric capacitor with a view to prevent the penetration of moisture and the diffusion of hydrogen, and so on. For example, there is an art in which the aluminum oxide film is formed to directly wrap the ferroelectric capacitor. Besides, there also is an art in which the aluminum oxide film is formed at further upward of a wiring layer positioning above the ferroelectric capacitor. Those arts are described in, for example, Patent Documents 1 to 5.

However, it cannot be said that the ferroelectric properties are enough secured by the above-stated conventional arts.
Patent Document 1: Japanese Patent Application Laid-open No. 2003-197878
Patent Document 2: Japanese Patent Application Laid-open No. 2001-68639
Patent Document 3: Japanese Patent Application Laid-open No. 2003-174145
Patent Document 4: Japanese Patent Application Laid-open No. 2002-176149
Patent Document 5: Japanese Patent Application Laid-open No. 2003-100994

### SUMMARY OF THE INVENTION

It is an aspect of the embodiments discussed herein to provide a semiconductor device, including: a ferroelectric capacitor above a semiconductor substrate, and including a bottom electrode, a ferroelectric film and a top electrode; a first wiring above the ferroelectric capacitor, a part of the first wiring being connected to one of the top electrode and bottom electrode; a barrier layer directly covering the first wiring, and preventing diffusion of hydrogen or moisture, a surface of the barrier layer being flat; an interlayer insulating film on the barrier layer; and a second wiring on the interlayer insulating film, a part of the second wiring being connected to the first wiring.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 is a sectional view showing a structure of a ferroelectric memory (semiconductor device) according to a reference example;

FIG. 2A is a plan view showing a ferroelectric memory according to a first embodiment;

FIG. 2B is a sectional view showing the ferroelectric memory according to the first embodiment;

FIG. 3A is a sectional view showing a manufacturing method of the ferroelectric memory according to the first embodiment;

FIG. 3B is a sectional view showing the manufacturing method of the ferroelectric memory following to FIG. 3A;

FIG. 3C is a sectional view showing the manufacturing method of the ferroelectric memory following to FIG. 3B;

FIG. 3D is a sectional view showing the manufacturing method of the ferroelectric memory following to FIG. 3C;

FIG. 3E is a sectional view showing the manufacturing method of the ferroelectric memory following to FIG. 3D;

FIG. 3F is a sectional view showing the manufacturing method of the ferroelectric memory following to FIG. 3E;

FIG. 3G is a sectional view showing the manufacturing method of the ferroelectric memory following to FIG. 3F;

FIG. 3H is a sectional view showing the manufacturing method of the ferroelectric memory following to FIG. 3G;

FIG. 3I is a sectional view showing the manufacturing method of the ferroelectric memory following to FIG. 3H;

FIG. 3J is a sectional view showing the manufacturing method of the ferroelectric memory following to FIG. 3I;

FIG. 3K is a sectional view showing the manufacturing method of the ferroelectric memory following to FIG. 3J;

FIG. 3L is a sectional view showing the manufacturing method of the ferroelectric memory following to FIG. 3K;

FIG. 3M is a sectional view showing the manufacturing method of the ferroelectric memory following to FIG. 3L;

FIG. 3N is a sectional view showing the manufacturing method of the ferroelectric memory following to FIG. 3M;

FIG. 3O is a sectional view showing the manufacturing method of the ferroelectric memory following to FIG. 3N;

FIG. 3P is a sectional view showing the manufacturing method of the ferroelectric memory following to FIG. 3O;

FIG. 3Q is a sectional view showing the manufacturing method of the ferroelectric memory following to FIG. 3P;

FIG. 3R is a sectional view showing the manufacturing method of the ferroelectric memory following to FIG. 3Q;

FIG. 3S is a sectional view showing the manufacturing method of the ferroelectric memory following to FIG. 3R;

FIG. 3T is a sectional view showing the manufacturing method of the ferroelectric memory following to FIG. 3S;

FIG. 3U is a sectional view showing the manufacturing method of the ferroelectric memory following to FIG. 3T;

FIG. 3V is a sectional view showing the manufacturing method of the ferroelectric memory following to FIG. 3U;

FIG. 3W is a sectional view showing the manufacturing method of the ferroelectric memory following to FIG. 3V;

FIG. 3X is a sectional view showing the manufacturing method of the ferroelectric memory following to FIG. 3W;

FIG. 3Y is a sectional view showing the manufacturing method of the ferroelectric memory following to FIG. 3X;

FIG. 4 is a sectional view showing the manufacturing method of the ferroelectric memory following to FIG. 3Q as same as FIG. 3R;

FIG. 5A is a view showing a leaving path of moisture in the first embodiment;

FIG. 5B is a view showing a leaving path of moisture in the reference example;

FIG. 6A is a sectional view showing a manufacturing method of a ferroelectric memory according to a second embodiment;

FIG. 6B is a sectional view showing the manufacturing method of the ferroelectric memory following to FIG. 6A;

FIG. 7 is a sectional view showing the ferroelectric memory according to the second embodiment;

FIG. 8 is a sectional view showing a ferroelectric memory according to a third embodiment; and

FIG. 9 is a sectional view showing a ferroelectric memory according to a fourth embodiment.

### DETAILED DESCRIPTION OF THE EMBODIMENTS

Hereinafter, embodiments are concretely described with reference to the attached drawings.

### Reference Example

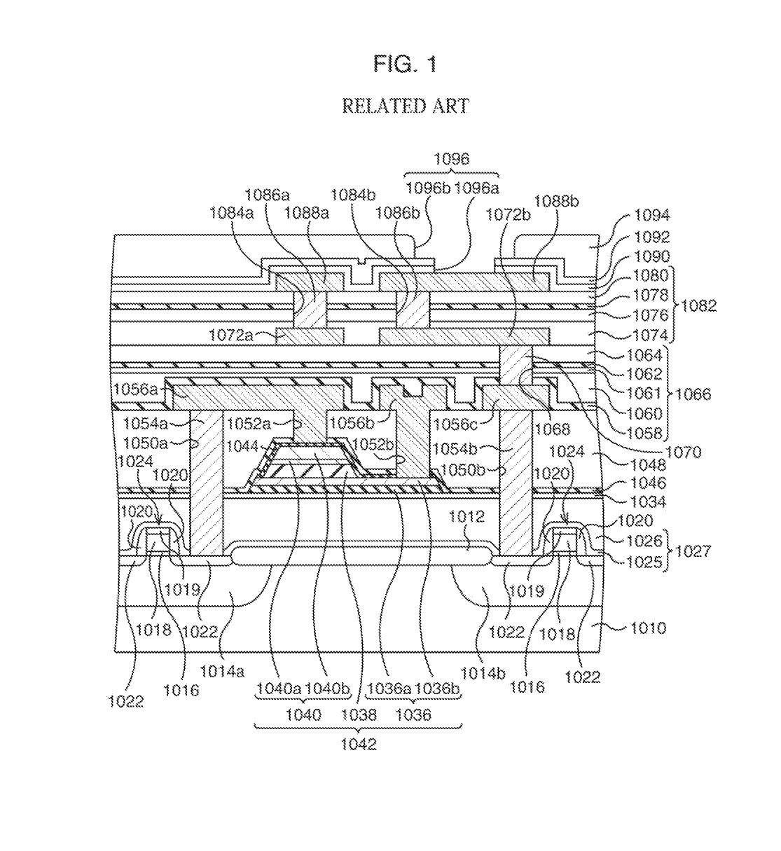

First, a reference example is described. This reference example is an art in which the present inventors came to an idea during a process reaching the present embodiment. FIG. 1 is a sectional view showing a structure of a ferroelectric memory (semiconductor device) according to the reference example.

As shown in FIG. 1, an element isolation region 1012 defining element regions is formed on a semiconductor substrate 1010 such as a silicon substrate. Wells 1014a and 1014b are formed in the element regions defined by the element isolation region 1012.

Gate electrodes (gate wirings) 1018 are formed on the wells 1014a and 1014b via gate insulating films 1016. The gate electrode 1018 has a polycide structure in which, for example, a metal silicide film such as a tungsten silicide film is formed on a poly-silicon film. An insulating film 1019 such as a silicon oxide film is formed on the gate electrode 1018. A sidewall insulating film 1020 is formed at lateral sides of the gate electrode 1018 and the insulating film 1019.

Source/drain diffusion layers 1022 are formed at surfaces of the wells 1014a and 1014b so as to sandwich the gate electrode 1018 in a plan view. Thus, transistors 1024 each having the gate electrode 1018 and the source/drain diffusion layers 1022 are constituted. A gate length of the transistor 1024 is, for example, 0.35 μm, or 0.11 μm to 0.18 μm.

Further, a SiON film 1025 and a silicon oxide film 1026 covering the transistors 1024 are sequentially formed. A thickness of the SiON film 1025 is, for example, 200 nm, and a thickness of the silicon oxide film 1026 is, for example, 600 nm. An interlayer insulating film 1027 is composed of the SiON film 1025 and the silicon oxide film 1026. A surface of the interlayer insulating film 1027 is flattened.

A silicon oxide film 1034 of which film thickness is, for example, 100 nm is formed on the interlayer insulating film 1027. The silicon oxide film 1034 is also flat because it is formed on the flattened interlayer insulating film 1027.

A bottom electrode 1036 is formed on the silicon oxide film 1034. The bottom electrode 1036 is composed of, for example, an aluminum oxide film 1036a of which film thickness is 20 nm to 50 nm and a Pt film 1036b of which film thickness is 100 nm to 200 nm formed thereon.

A ferroelectric film 1038 is formed on the bottom electrode 1036. As the ferroelectric film 1038, a PbZr_{1-X}Ti_{X}O₃ film (PZT film) of which film thickness is, for example, 100 nm to 250 nm is used.

A top electrode 1040 is formed on the ferroelectric film 1038. The top electrode 1040 is composed of, for example, an IrO_{X} film 1040a of which film thickness is 25 nm to 75 nm and an IrO_{Y} film 1040b of which film thickness is 150 nm to 250 nm formed thereon. Incidentally, a composition ratio Y of oxygen of the IrO_{Y} film 1040b is set to be higher than a composition ratio X of the oxygen of the IrO_{X} film 1040a.

A ferroelectric capacitor 1042 is composed of the bottom electrode 1036, the ferroelectric film 1038 and the top electrode 1040.

A barrier film 1044 is formed so as to cover an upper surface and side surfaces of the ferroelectric film 1038 and the top electrode 1040. As the barrier film 1044, an aluminum oxide (Al₂O₃) film of which thickness is, for example, 20 nm to 100 nm is used.

The barrier film 1044 is a film having a function preventing diffusion of hydrogen and moisture. If hydrogen or moisture reaches the ferroelectric film 1038, a metal oxide constituting the ferroelectric film 1038 is reduced by the hydrogen or moisture, and an electric property of the ferroelectric capacitor 1042 deteriorates. With the barrier film 1044 being formed to cover the upper surface and side surfaces of the ferroelectric film 1038 and the top electrode 1040, it is possible to suppress the deterioration of the electric property of the ferroelectric capacitor 1042 because it is suppressed that hydrogen and moisture reach the ferroelectric film 1038.

Further, a barrier film 1046 covering the barrier film 1044 and the ferroelectric capacitor 1042 is formed. For example, an aluminum oxide film of which film thickness is 20 nm to 100 nm is used as the barrier film 1046. The barrier film 1046 is a film having a function preventing the diffusion of hydrogen and moisture as same as the barrier film 1044.

An interlayer insulating film 1048 such as a silicon oxide film of which film thickness is, for example, 1500 nm is formed on the barrier film 1046. A surface of the interlayer insulating film 1048 is flattened.

Contact holes 1050a and 1050b reaching the source/drain diffusion layer 1022 are formed in the interlayer insulating film 1048, the barrier film 1046, the silicon oxide film 1034 and the interlayer insulating film 1027. Besides, a contact hole 1052a reaching the top electrode 1040 is formed in the interlayer insulating film 1048, the barrier film 1046 and the barrier film 1044. Further, a contact hole 1052b reaching the bottom electrode 1036 is formed in the interlayer insulating film 1048, the barrier film 1046 and the barrier film 1044.

Barrier metal films (not shown) are formed inside the contact holes 1050a and 1050b. The barrier metal film is composed of, for example, a Ti film of which film thickness is 20 nm and a TiN film of which film thickness is 50 nm formed thereon. Within the barrier metal film, the Ti film is formed to reduce a contact resistance, and the TiN film is formed to prevent the diffusion of tungsten of a conductive plug material. Barrier metal films formed in each of later-described contact holes are formed for similar purposes.

Further, conductive plugs 1054a and 1054b composed of tungsten are respectively embedded inside the contact holes 1050a and 1050b, in which the barrier metal films are formed.

A wiring 1056a electrically connected to the conductive plug 1054a and the top electrode 1040 is formed on the interlayer insulating film 1048 and inside the contact hole 1052a. Besides, a wiring 1056b electrically connected to the bottom electrode 1036 is formed on the interlayer insulating film 1048 and inside the contact hole 1052b. Further, a wiring 1056c electrically connected to the conductive plug 1054b is formed on the interlayer insulating film 1048. The wirings 1056a, 1056b and 1056c (a first metal wiring layer 1056) are composed of, for example, a TiN film of which film thickness is 150 nm, an AlCu alloy film of which film thickness is 550 nm formed thereon, a Ti film of which film thickness is 5 nm formed thereon and a TiN film of which film thickness is 150 nm formed thereon.

Thus, the source/drain diffusion layer 1022 of the transistor 1024 and the top electrode 1040 of the ferroelectric capacitor 1042 are electrically connected via the conductive plug 1054a and the wiring 1056a, and a 1T1C-type memory cell of FeRAM having one transistor 1024 and one ferroelectric capacitor 1042 is constituted. Plural memory cells are arranged in a memory cell region of an FeRAM chip though they are not shown.

Further, a barrier film 1058 covering upper surfaces and side surfaces of the wirings 1056a, 1056b and 1056c is formed. An aluminum oxide film of which film thickness is, for example, 20 nm is used as the barrier film 1058.

The barrier film 1058 is a film having a function preventing the diffusion of hydrogen and moisture as same as the barrier films 1044 and 1046. Besides, the barrier film 1058 is also used to suppress damage by plasma.

A silicon oxide film 1060 of which film thickness is, for example, 2600 nm is formed on the barrier film 1058. A surface of the silicon oxide film 1060 is flattened. A thickness of the silicon oxide film 1060 on the wirings 1056a, 1056b and 1056c is, for example, 1000 nm.

A silicon oxide film 1061 of which film thickness is, for example, 100 nm is formed on the silicon oxide film 1060. The silicon oxide film 1061 is also flat because it is formed on the flattened silicon oxide film 1060.

A barrier film 1062 is formed on the silicon oxide film 1061. An aluminum oxide film of which film thickness is, for example, 20 nm to 70 nm is used as the barrier film 1062. The barrier film 1062 is also flat because it is formed on the flat silicon oxide film 1061.

The barrier film 1062 is a film having a function to prevent the diffusion of hydrogen and moisture as same as the barrier films 1044, 1046 and 1058. Further, the barrier film 1062 is flat, and therefore, it is formed with extremely good coverage (covering property) compared to the barrier films 1044, 1046 and 1058. Consequently, it is possible to prevent the diffusion of hydrogen and moisture more surely. Incidentally, the barrier film 1062 is formed not only on the memory cell region of the FeRAM chip where plural memory cells having the ferroelectric capacitors 1042 are arranged, but also for a whole surface of the FeRAM chip including a peripheral circuit region and so on.

A silicon oxide film 1064 of which film thickness is, for example, 50 nm to 100 nm is formed on the barrier film 1062.

An interlayer insulating film 1066 is composed of the barrier film 1058, the silicon oxide film 1060, the silicon oxide film 1061, the barrier film 1062 and the silicon oxide film 1064.

A contact hole 1068 reaching the wiring 1056c is formed in the interlayer insulating film 1066.

A barrier metal film (not shown) is formed inside the contact hole 1068. The barrier metal film is composed of, for example, a Ti film of which film thickness is 20 nm and a TiN film of which film thickness is 50 nm formed thereon. Incidentally, the barrier metal film may be composed of only the TiN film without the Ti film.

A conductive plug 1070 composed of tungsten is embedded inside the contact hole 1068, in which the barrier metal film is formed.

A wiring 1072a is formed on the interlayer insulating film 1066. Besides, a wiring 1072b electrically connected to the conductive plug 1070 is formed on the interlayer insulating film 1066. The wirings 1072a and 1072b (a second metal wiring layer 1072) are composed of, for example, a TiN film of which film thickness is 50 nm, an AlCu alloy film of which film thickness is 500 nm formed thereon, a Ti film of which film thickness is 5 nm formed thereon and a TiN film of which film thickness is 150 nm formed thereon.

Further, a silicon oxide film 1074 covering the wirings 1072a and 1072b is formed. A thickness of the silicon oxide film 1074 is, for example, 2200 nm. A surface of the silicon oxide film 1074 is flattened.

A silicon oxide film 1076 of which film thickness is, for example, 100 nm is formed on the silicon oxide film 1074. The silicon oxide film 1076 is also flat because it is formed on the flattened silicon oxide film 1074.

A barrier film 1078 is formed on the silicon oxide film 1076. An aluminum oxide film of which film thickness is, for example, 20 nm to 100 nm is used as the barrier film 1078. The barrier film 1078 is also flat because it is formed on the flat silicon oxide film 1076.

The barrier film 1078 is a film having a function preventing the diffusion of hydrogen and moisture as same as the barrier films 1044, 1046, 1058 and 1062. Further, the barrier film 1078 is flat, and therefore, it is formed with an extremely good coverage (covering property) as same as the barrier film 1062 compared to the barrier films 1044, 1046 and 1058. Consequently, it is possible to prevent the diffusion of hydrogen and moisture more surely. Incidentally, the barrier film 1078 is formed not only on the memory cell region of the FeRAM chip where plural memory cells having the ferroelectric capacitors 1042 are arranged, but also for a whole surface of the FeRAM chip including a peripheral circuit region and so on.

A silicon oxide film 1080 of which film thickness is, for example, 100 nm is formed on the barrier film 1078.

An interlayer insulating film 1082 is composed of the silicon oxide film 1074, the silicon oxide film 1076, the barrier film 1078 and the silicon oxide film 1080.

Contact holes 1084a and 1084b respectively reaching the wirings 1072a and 1072b are formed in the interlayer insulating film 1082.

Barrier metal films (not shown) are formed inside the contact holes 1084a and 1084b. The barrier metal film is composed of by, for example, a Ti film of which film thickness is 20 nm and a TiN film of which film thickness is 50 nm formed thereon. Incidentally, the barrier metal film may be composed of only the TiN film without the Ti film.

Conductive plugs 1086a and 1086b composed of tungsten are respectively embedded inside the contact holes 1084a and 1084b, in which the barrier metal films are formed.

A wiring 1088a electrically connected to the conductive plug 1086a and a wiring (bonding pad) 1088b electrically connected to the conductive plug 1086b are formed on the interlayer insulating film 1082. The wirings 1088a and 1088b (a third metal wiring layer 1088) are composed of, for example, a TiN film of which film thickness is 50 nm, an AlCu alloy film of which film thickness is 500 nm formed thereon and a TiN film of which film thickness is 150 nm formed thereon.

Further, a silicon oxide film 1090 covering the wirings 1088a and 1088b is formed. A thickness of the silicon oxide film 1090 is, for example, 100 nm to 300 nm. A silicon nitride film 1092 of which film thickness is, for example, 350 nm is formed on the silicon oxide film 1090. A polyimide resin film 1094 of which film thickness is, for example, 2 μm to 6 μm is formed on the silicon nitride film 1092.

An opening 1096 reaching the wiring (bonding pad) 1088b is formed in the polyimide resin film 1094, the silicon nitride film 1092 and the silicon oxide film 1090. In other words, an opening 1096a reaching the wiring (bonding pad) 1088b is formed in the silicon nitride film 1092 and the silicon oxide film 1090. Further, an opening 1096b is formed in the polyimide resin film 1094 at a region including the opening 1096a.

An external circuit (not-shown) is electrically connected to the wiring (bonding pad) 1088b via the opening 1096.

Thus, the semiconductor device according to the reference example is constituted.

In the semiconductor device as described above, the barrier films 1062 and 1078, which are flat and have good coverage (covering property), are formed in addition to the barrier films 1044, 1046 and 1058, and therefore, it is possible to interrupt hydrogen and moisture, and to prevent that hydrogen and moisture reach the ferroelectric film 1038 more surely. Namely, even if defects occur at both of the barrier films 1062 and 1078, it is possible to prevent the penetration of hydrogen and moisture by at least one of the barrier films because defected positions may be displaced from one another in most cases.

However, it turned out that there is a case when defect may occur in the barrier metal film and the tungsten film when the conductive plugs 1070, 1086a and 1086b are formed, in the reference example as described above. A factor of the above was studied, and it was found that the moisture left from the silicon oxide films 1060, 1061, 1074 and 1076 under the barrier film 1062 or 1078 remains while adhering on sidewalls of the contact holes 1068, 1084a and 1084b, at the time of a high-temperature process at approximately 400° C. performed when the barrier metal film and the tungsten film are formed.

It is preferable that NSG (Non-Silicate-Glass) films formed by a plasma CVD method in which source gas is TEOS (Tetra-Ethyl-Ortho-Silicate) are used for the silicon oxide films 1060, 1061, 1074 and 1076, but moisture remains within the films. The moisture is leaving from inside the films at the time of the high-temperature process after that. However, in the above-described reference example, the barrier film 1062 or 1078 exists over the silicon oxide film 1060, 1061, 1074 or 1076, and therefore, the moisture cannot get out to upward. Accordingly, the moisture gathers to the sidewall of the contact hole 1068, 1084a or 1084b so as to get out of the films. As a result, the moisture, which reaches the sidewalls but is unable to completely leave toward outside, remains at the sidewalls of the contact holes or inside thereof. Accordingly, growths of the barrier metal film and the tungsten film are disturbed.

The present inventors therefore studied further more, and came to embodiments as stated below.

### First Embodiment

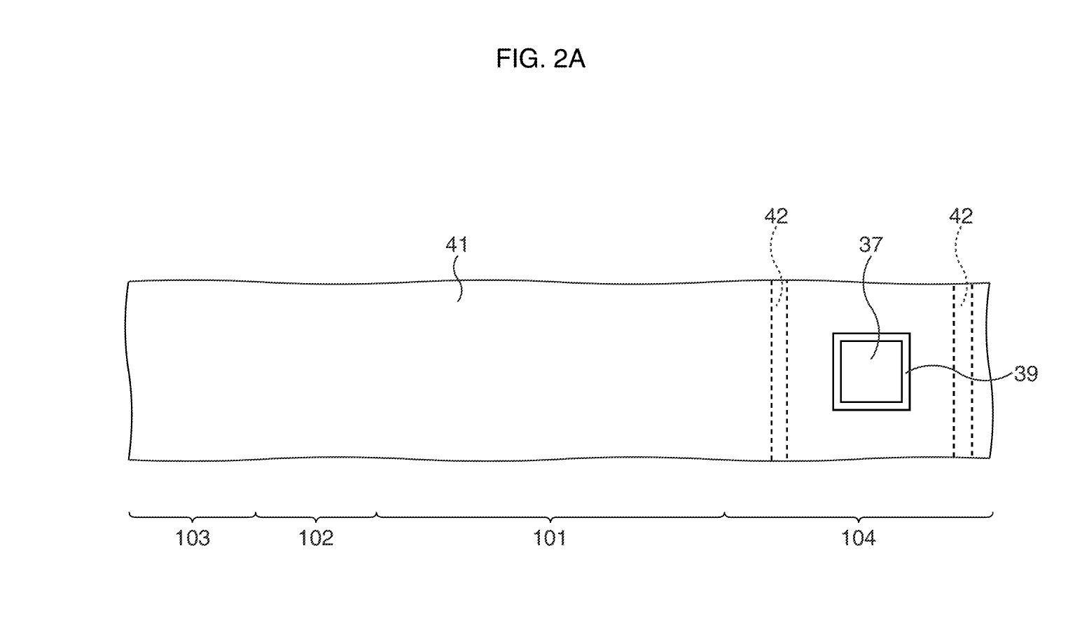

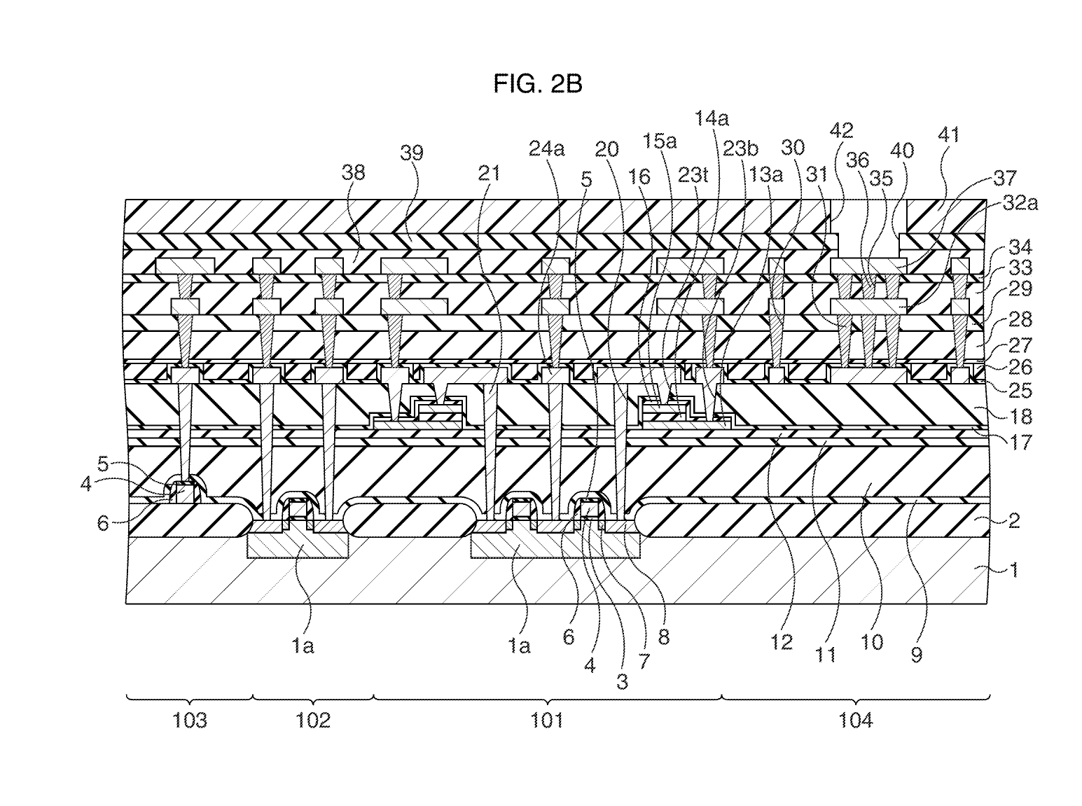

Here, a first embodiment is described. FIG. 2A is a plan view showing a ferroelectric memory (semiconductor device) according to the first embodiment, and FIG. 2B is a sectional view similarly showing the ferroelectric memory.

As shown in FIG. 2A and FIG. 2B, the ferroelectric memory according to the first embodiment may be defined into a memory cell portion 101, a logic circuit portion 102, a peripheral circuit portion 103 and a pad portion 104. In FIG. 2A and FIG. 2B, these portions are arranged in one direction, but it is not necessary that these portions are arranged in one direction, and more elements and so on are provided at respective portions.

In the present embodiment, element isolation regions 2 defining element regions are formed on a semiconductor substrate 1 such as a silicon substrate. Wells 1a are formed in the element regions defined by the element isolation regions 2. A conductive type of the well 1a can be selected arbitrary in accordance with an element to be formed thereon.

Gate electrodes (gate wirings) 4 are formed on the wells 1a via gate insulating films 3. The gate electrode 4 has a polycide structure in which, for example, a metal silicide film such as a tungsten silicide film is formed on a poly-silicon film. A cap insulating film 5 such as a silicon oxide film is formed on the gate electrode 4. A sidewall insulating film 6 is formed at lateral sides of the gate electrode 4 and the cap insulating film 5.

Source/drain diffusion layers having an LDD structure are formed at surfaces of the wells 1a so as to sandwich the gate electrodes 4 in a plan view. A low-concentration diffusion layer 7 and a high-concentration diffusion layer 8 are provided to the source/drain diffusion layer. Thus, a transistor having the gate electrode 4 and the source/drain diffusion layers having the LDD structure is constituted. When the transistor is an N-channel MOS transistor, boron (B) is introduced to the well 1a, phosphorus (P) is introduced to the low-concentration diffusion layer 7, and arsenic (As) is introduced to the high-concentration diffusion layer 8.

Further, a SiON film 9 and a silicon oxide film 10 covering the transistor are sequentially formed. A surface of the silicon oxide film 10 is flattened. A silicon oxide film 11 and a barrier film 12 are sequentially formed on the silicon oxide film 10.

Bottom electrodes 13a are formed on the barrier film 12. A ferroelectric film 14a is formed on each of the bottom electrodes 13a. Further, a top electrode 15a is formed on each of the ferroelectric films 14a. A ferroelectric capacitor is composed of the bottom electrode 13a, the ferroelectric film 14a and the top electrode 15a.

A barrier film 16 is formed so as to cover an upper surface and side surfaces of the ferroelectric film 14a and the top electrode 15a. The barrier film 16 is a film having a function preventing diffusion of hydrogen and moisture. If hydrogen or moisture reaches the ferroelectric film 14a, a metal oxide composing the ferroelectric film 14a is reduced by the hydrogen or moisture, and an electric property of the ferroelectric capacitor deteriorates. With the barrier film 16 being formed so as to cover the upper surface and side surfaces of the ferroelectric film 14a and the top electrode 15a, it is possible to suppress the deterioration of the electric property of the ferroelectric capacitor because hydrogen and moisture are suppressed to reach the ferroelectric film 14a.

Further, a barrier film 17 covering the barrier film 16 and the ferroelectric capacitor is formed. The barrier film 17 is a film having the function to prevent the diffusion of hydrogen and moisture as same as the barrier film 16.

An interlayer insulating film 18 such as a silicon oxide film is formed on the barrier film 17. A surface of the interlayer insulating film 18 is flattened.

Contact holes 20 reaching the high-concentration diffusion layers 8 of the source/drain diffusion layers are formed in the interlayer insulating film 18, the barrier film 17, the barrier film 12, the silicon oxide film 11, the silicon oxide film 10 and the SiON film 9. Besides, contact holes 23t reaching the top electrodes 15a are formed in the interlayer insulating film 18, the barrier film 17 and the barrier film 16. Further, contact holes 23b reaching the bottom electrodes 13a are formed in the interlayer insulating film 18, the barrier film 17 and the barrier film 16.

Barrier metal films (not-shown) are formed inside the contact holes 23t and 23b. The barrier metal film is composed of, for example, a Ti film and a TiN film formed thereon. The Ti film is formed to reduce a contact resistance, and the TiN film is formed to prevent diffusion of tungsten of a conductive plug material within the barrier metal film. Barrier metal films formed in each of later-described contact holes are formed for similar purposes.

Further, conductive plugs 21 composed of tungsten are embedded inside the contact holes 23t and 23b, in which the barrier metal films are formed.

Wirings 24a (first wirings) are formed on the interlayer insulating film 18, and inside the contact holes 23t and 23b. One of the wirings 24a electrically connects the conductive plug 21 connected to the high-concentration diffusion layer 8 and the top electrode 15a.

Thus, the high-concentration diffusion layer 8 of the transistor and the top electrode 15a of the ferroelectric capacitor are electrically connected via the one of the wirings 24a, and a 1T1C-type memory cell of FeRAM having one transistor and one ferroelectric capacitor is constituted. Incidentally, plural memory cells are arranged in a memory cell region of an FeRAM chip though they are not shown.

Further, a barrier film 25 covering upper surfaces and side surfaces of the wirings 24a is formed. The barrier film 25 is formed to follow the wirings 24a, and therefore, concave and convex exist around the wirings 24a. In the present embodiment, a silicon oxide film 26 is formed so as to embed these concave and convex. Surfaces of the barrier film 25 and the silicon oxide film 26 are flattened.

A barrier film 27 is formed on the barrier film 25 and the silicon oxide film 26. Since the barrier film 25 and the silicon oxide film 26 are flattened, the barrier film 27 is also flat. Silicon oxide films 28 and 29 are sequentially formed on the barrier film 27. A surface of the silicon oxide film 29 is flattened. A barrier layer is composed of the barrier films 25 and 27. Besides, an interlayer insulating film is composed of the silicon oxide films 28 and 29.

Contact holes 30 reaching a part of the wirings 24a are formed in the silicon oxide film 29, the silicon oxide film 28, the barrier film 27 and the barrier film 25. Barrier metal films (not shown) are formed inside the contact holes 30. The barrier metal film is composed of, for example, a Ti film and a TiN film formed thereon. Incidentally, the barrier metal film may be composed of only the TiN film without the Ti film.

A conductive plug 31 composed of tungsten is embedded inside the contact hole 30 in which the barrier metal film is formed.

Wirings 32a (second wirings) in which a part thereof is connected to the conductive plugs 31 are formed on the silicon oxide film 28. Further, a silicon oxide film 33 covering the wirings 32a is formed. A surface of the silicon oxide film 33 is flattened. A silicon oxide film 34 is formed on the silicon oxide film 33. The silicon oxide film 34 is also flat because it is formed on the flattened silicon oxide film 33.

Contact holes 35 reaching ones of the wirings 32a are formed in the silicon oxide films 34 and 33. The barrier metal films (not shown) are formed inside the contact holes 35. The barrier metal film is composed of, for example, a Ti film and a TiN film formed thereon. Incidentally, the barrier metal film may be composed of only the TiN film without the Ti film.

A conductive plug 36 composed of tungsten is embedded inside the contact hole 35, in which the barrier metal film is formed.

Wirings 37 electrically connected to the conductive plugs 36 are formed on the silicon oxide film 34.

Further, a silicon oxide film 38 covering the wirings 37 is formed. A silicon nitride film 39 is formed on the silicon oxide film 38. An opening 40 exposing a part of the wiring 37 in the pad portion 104 is formed in the silicon oxide film 38 and the silicon nitride film 39. The portion of the wiring 37 exposed from the opening 40 functions as a bonding pad.

A polyimide resin film 41 is formed on the silicon nitride film 39. An opening 42 matching with the opening 40 in the pad portion 104 is formed in the polyimide resin film 41.

An external circuit (not-shown) is electrically connected to the portion functioning as the bonding pad of the wiring 37 via the openings 42 and 40.

Incidentally, some of the wirings and the contact holes are formed in a ring shape in the pad portion 104, and the portion functions as a moisture-resistant ring 42.

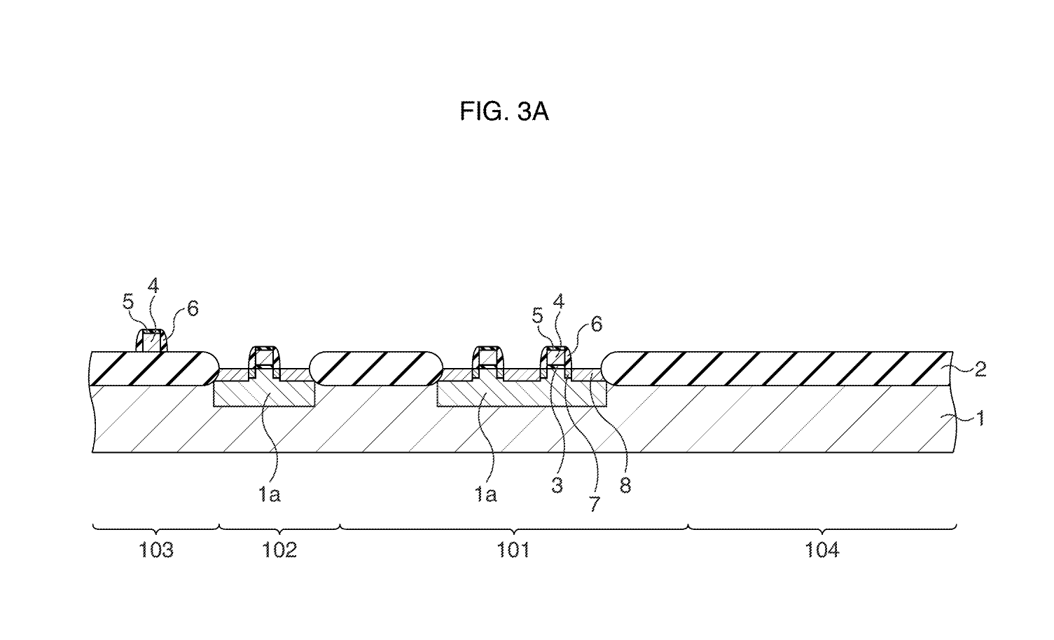

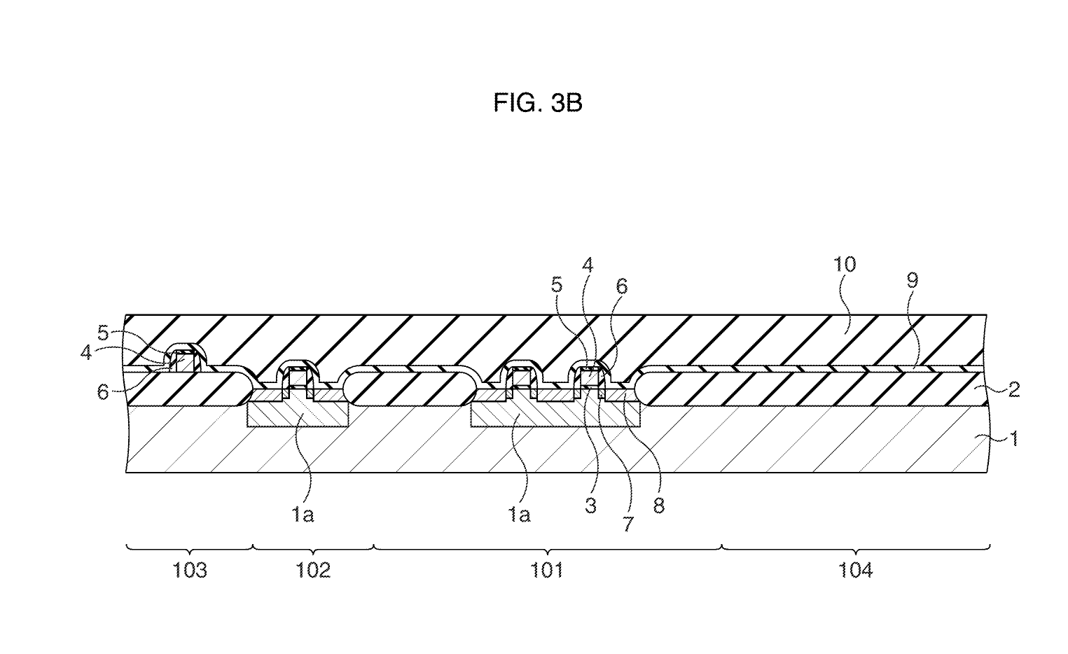

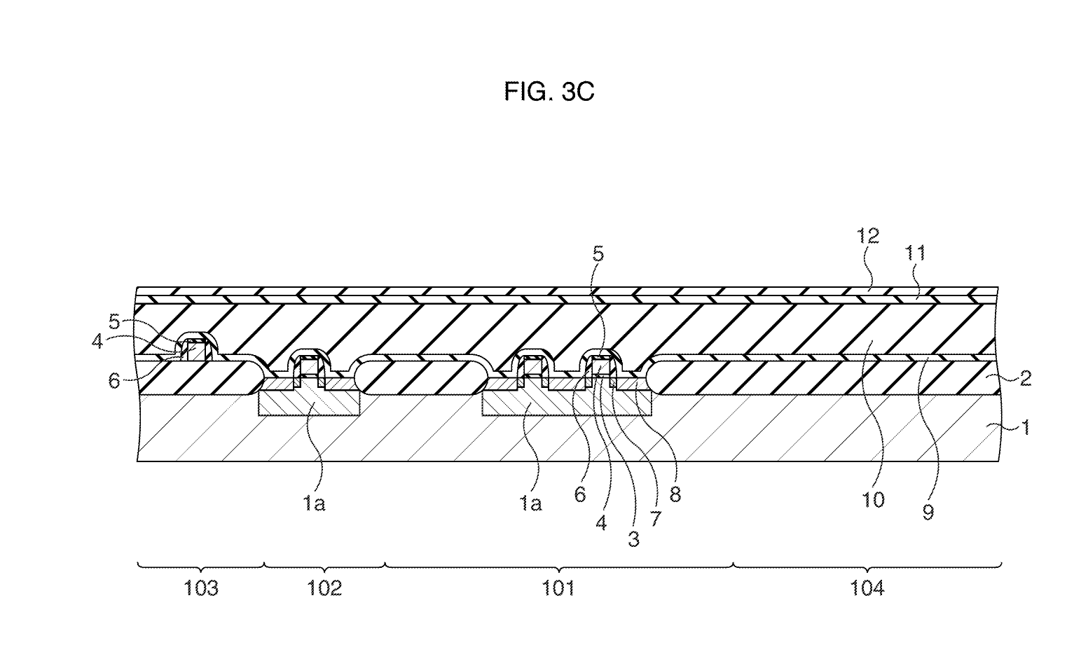

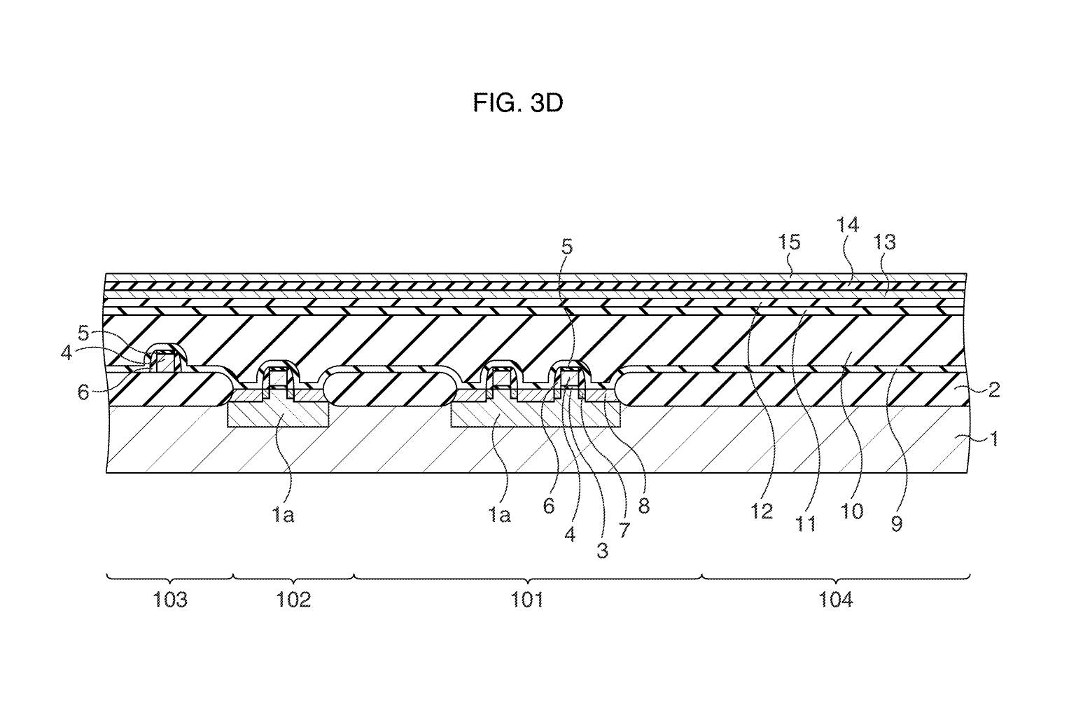

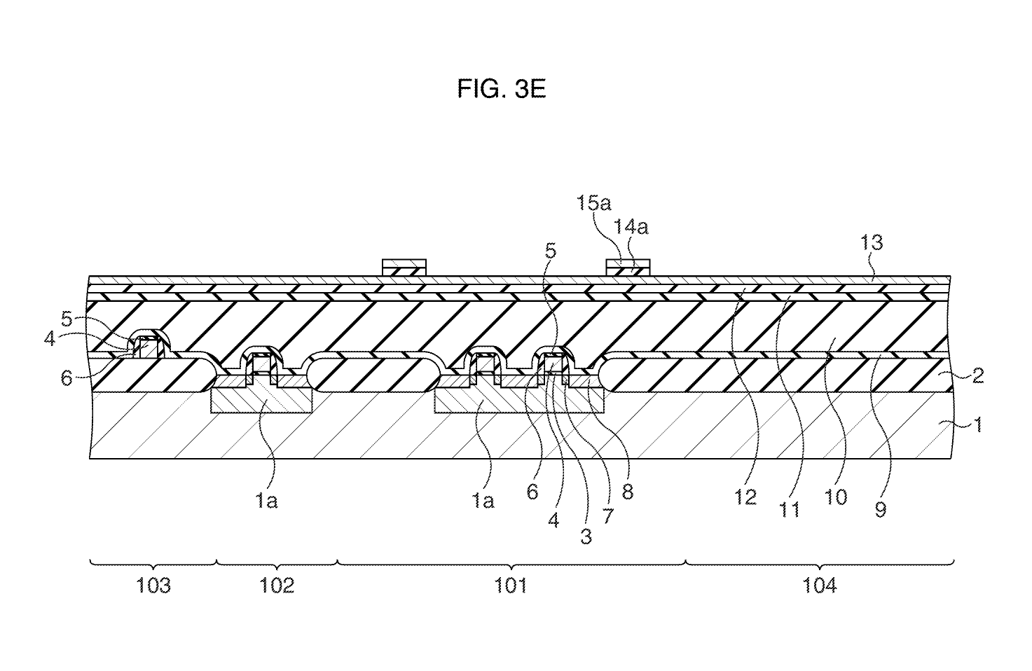

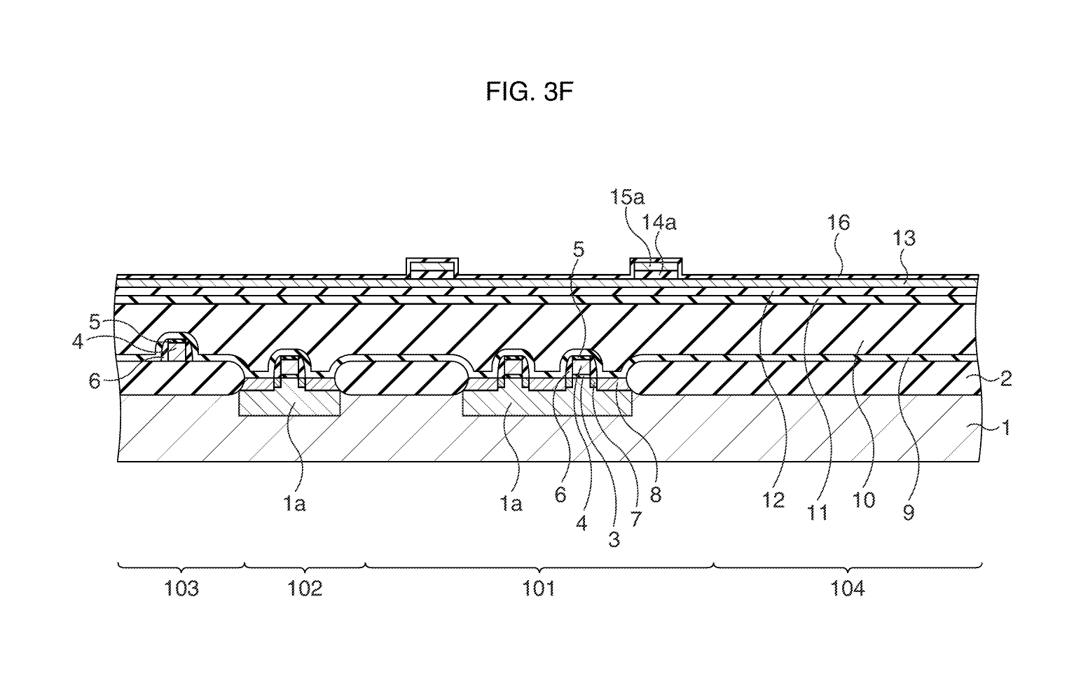

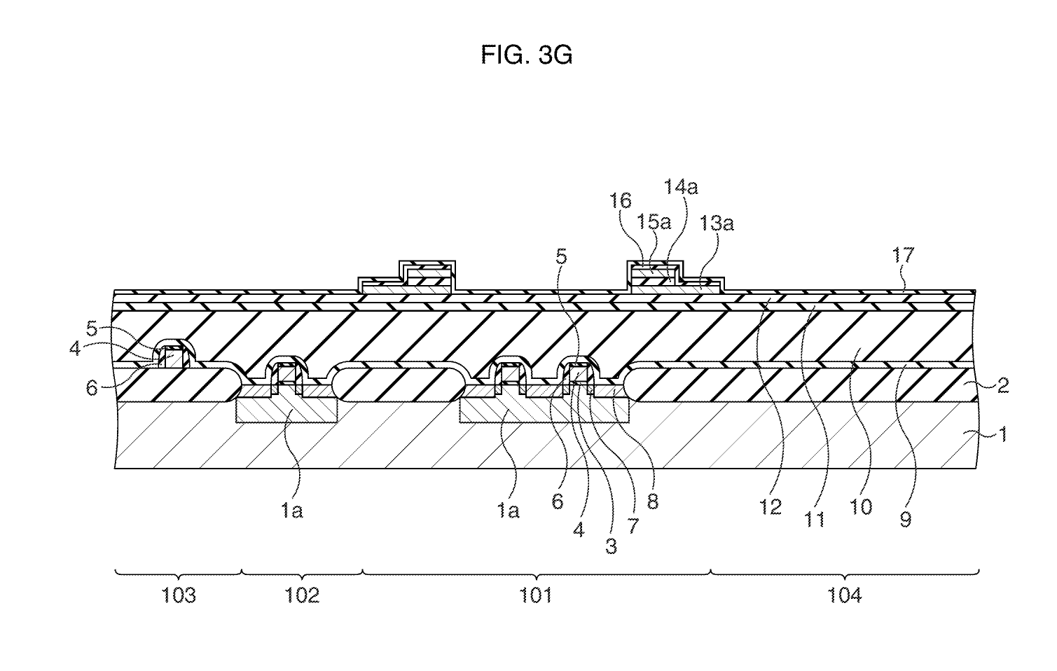

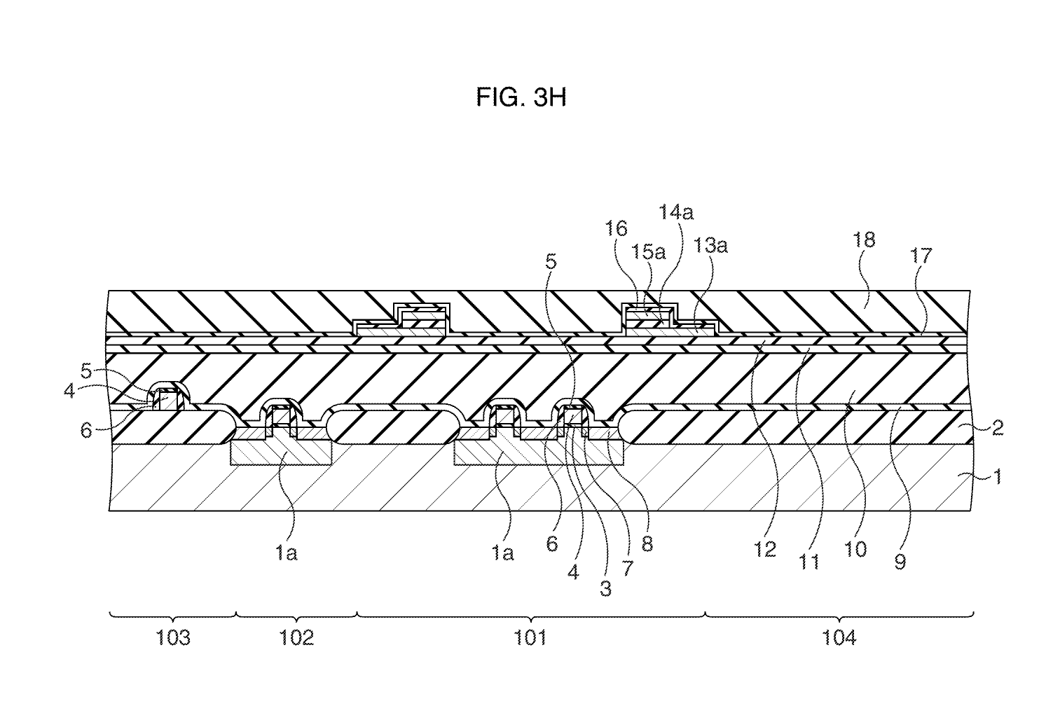

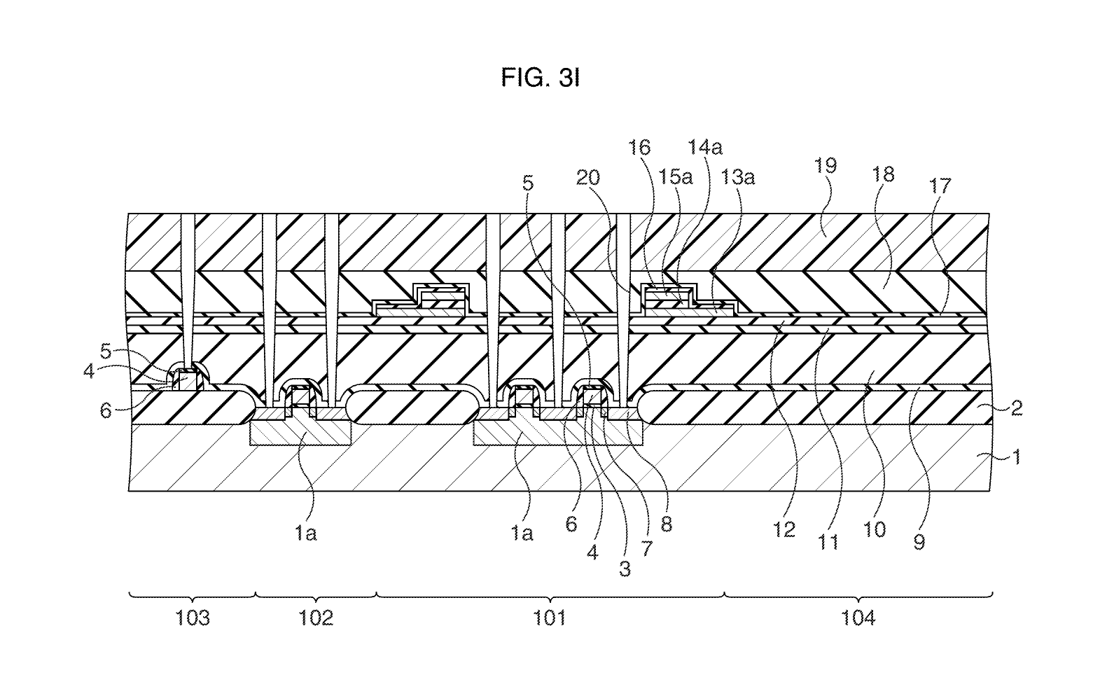

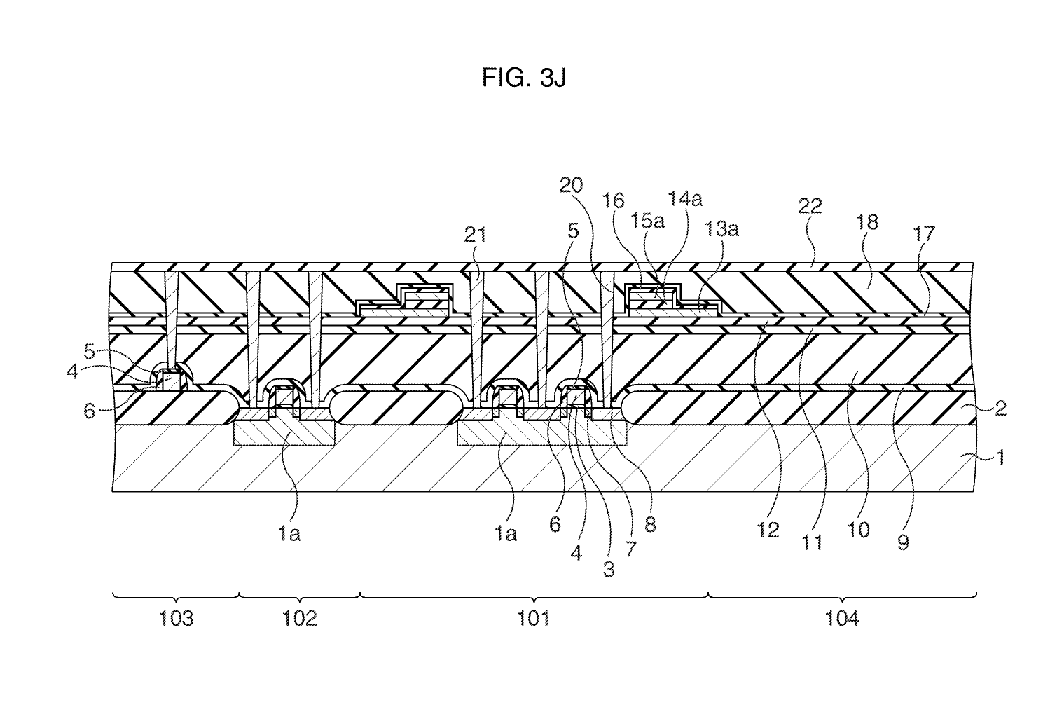

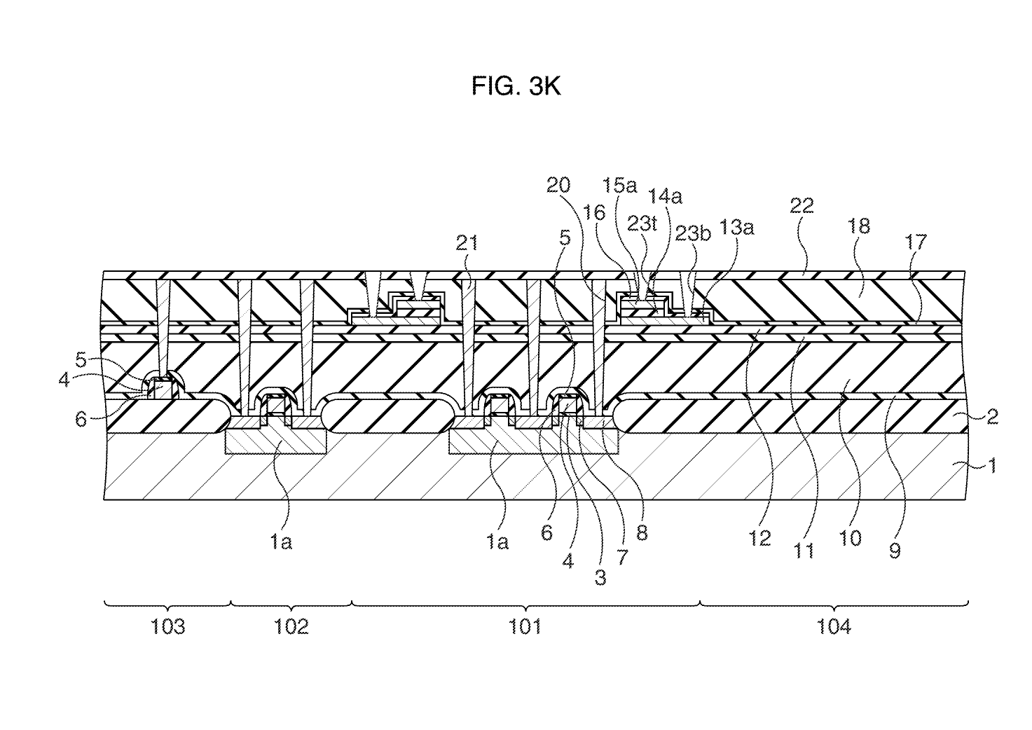

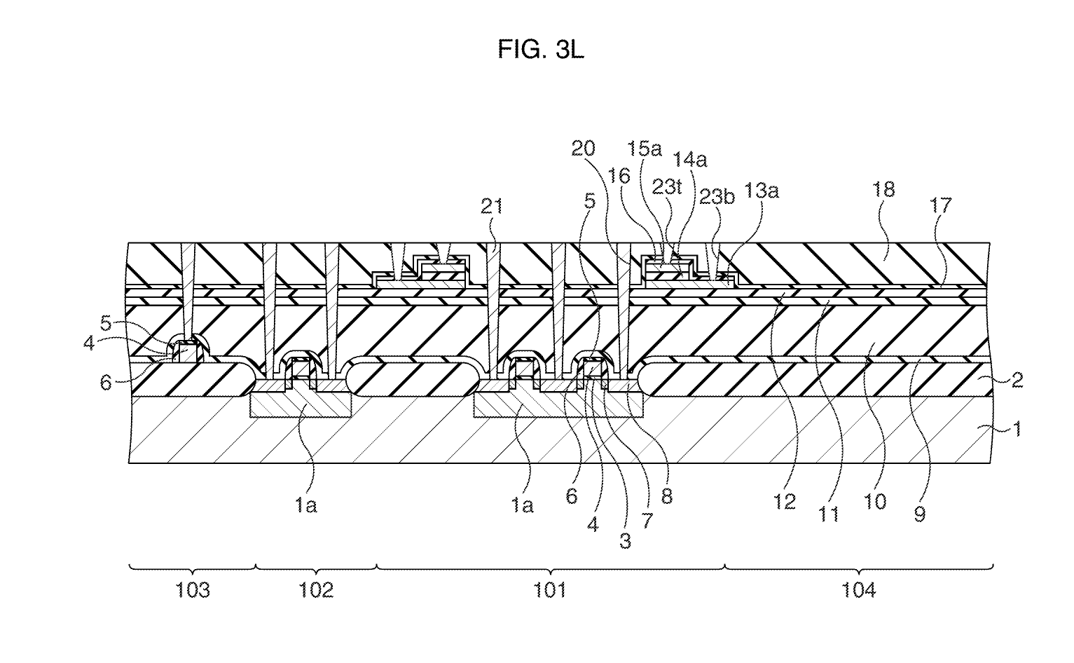

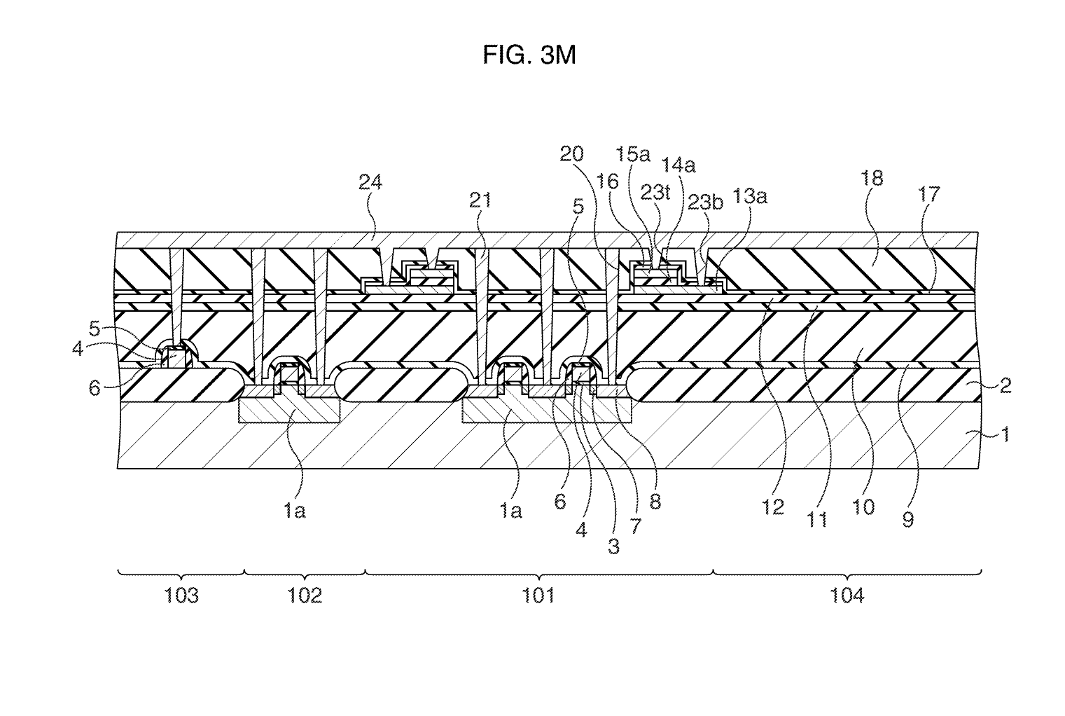

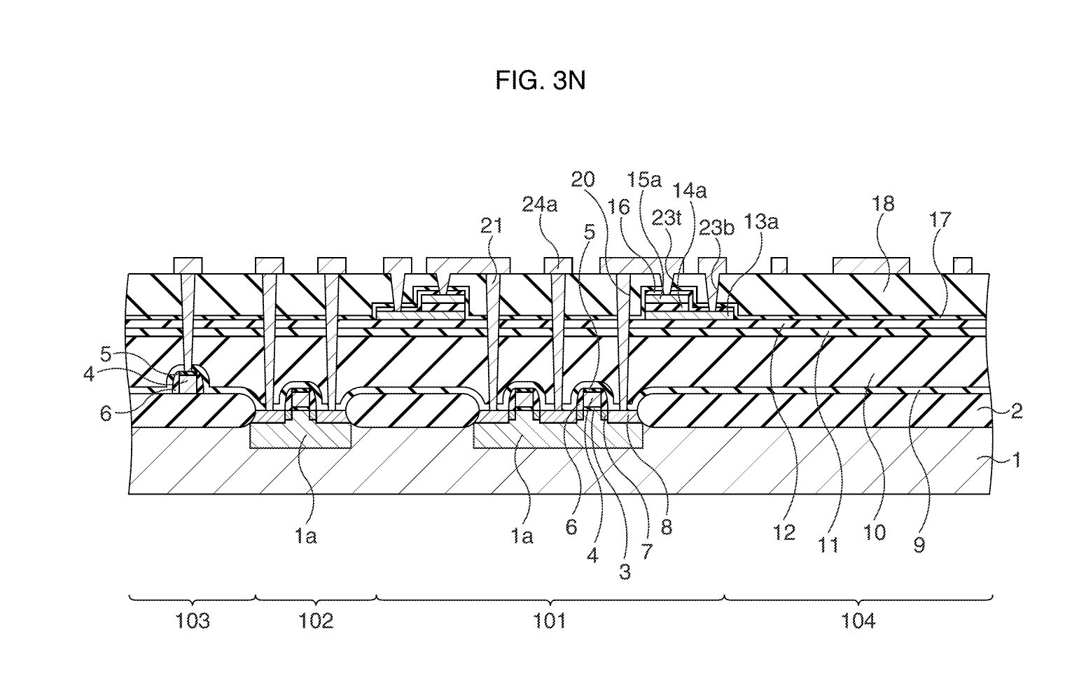

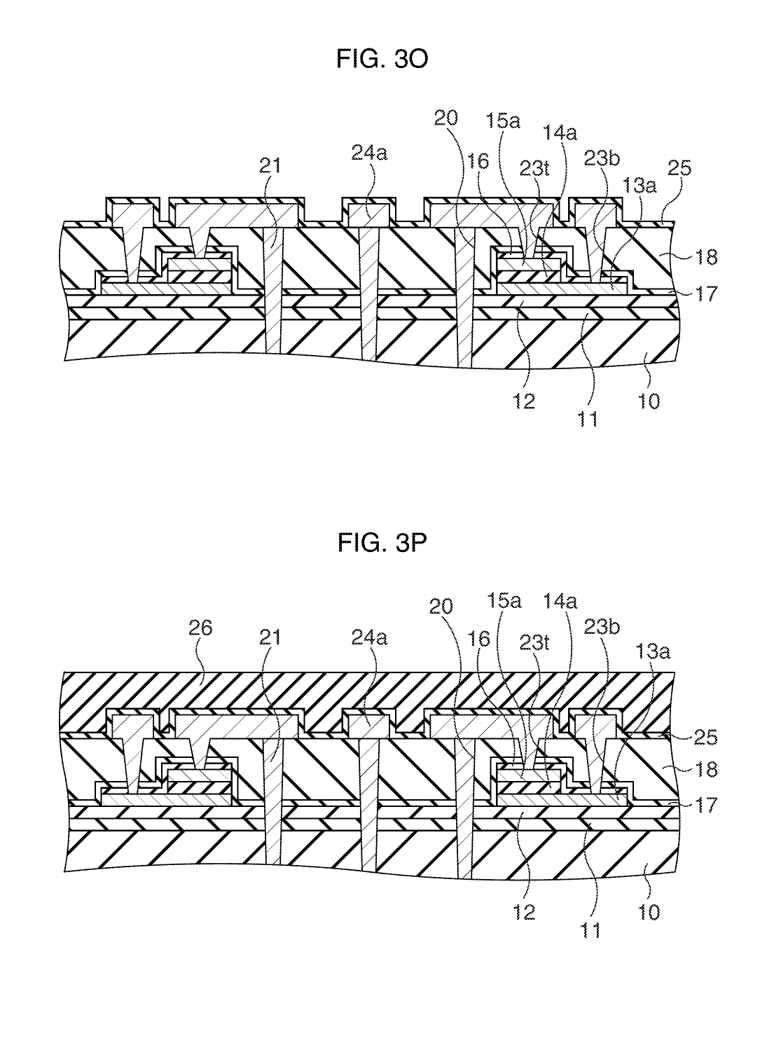

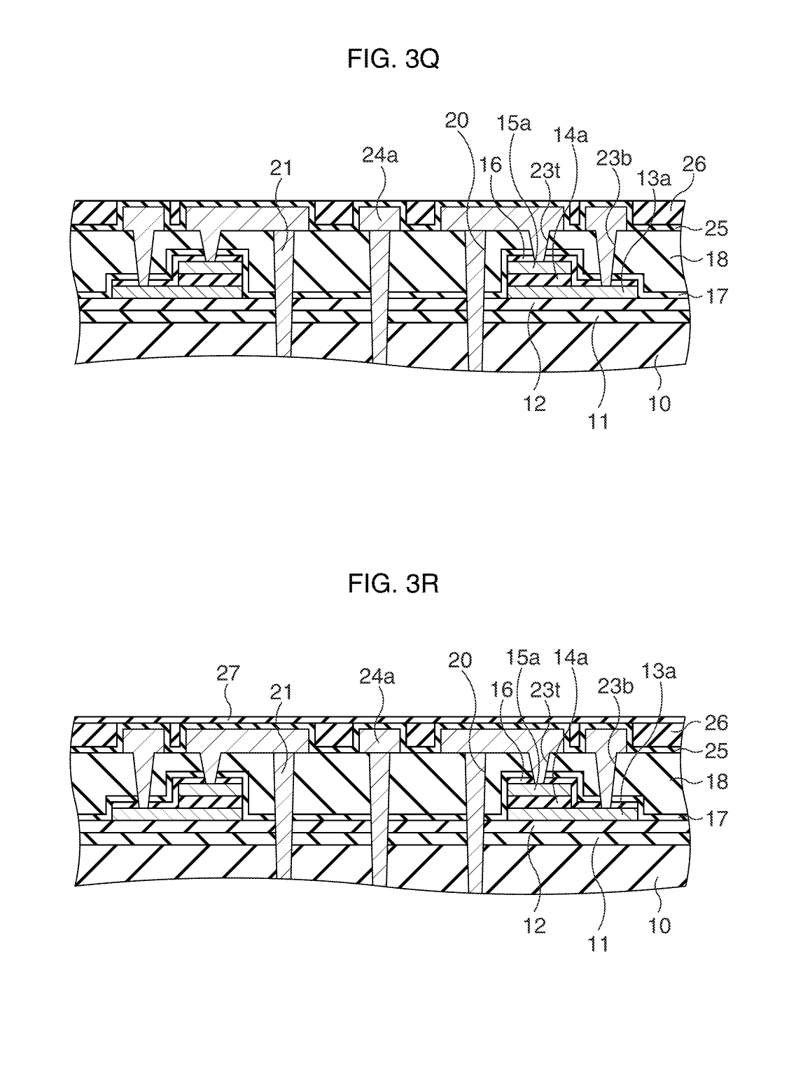

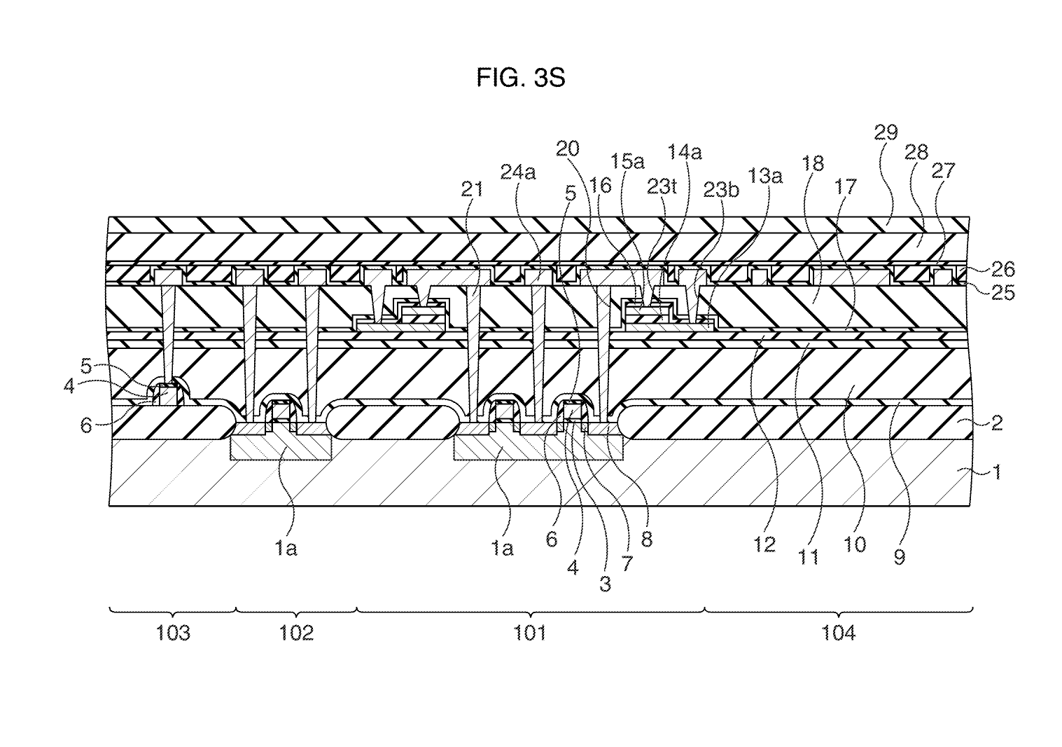

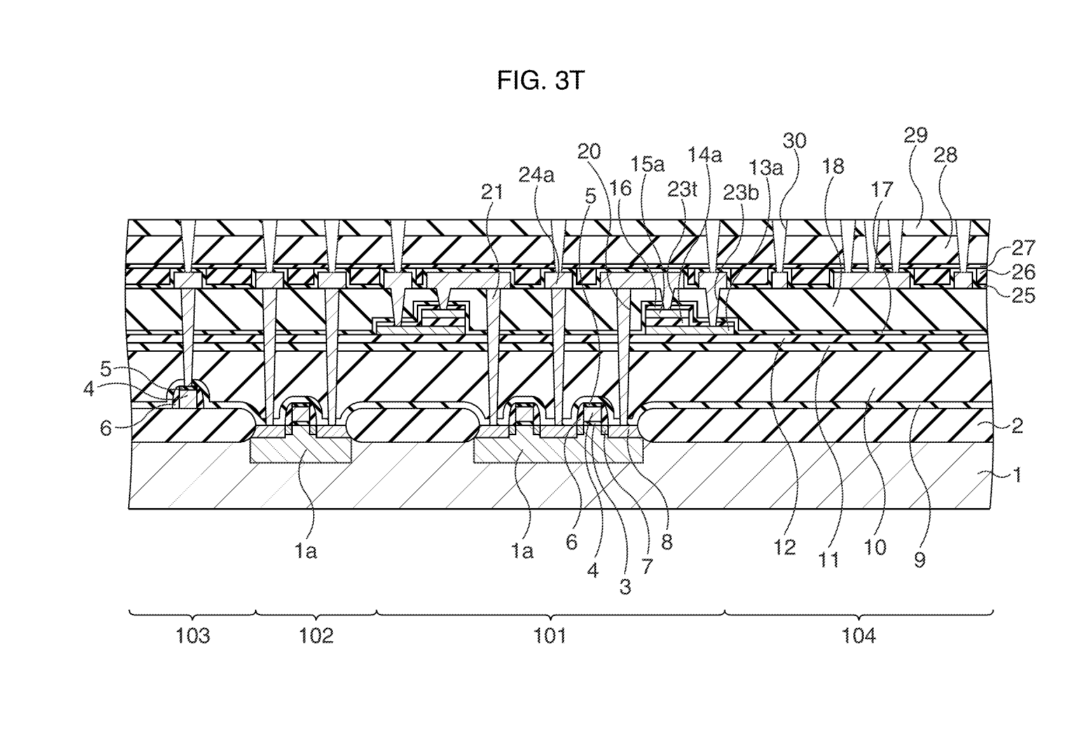

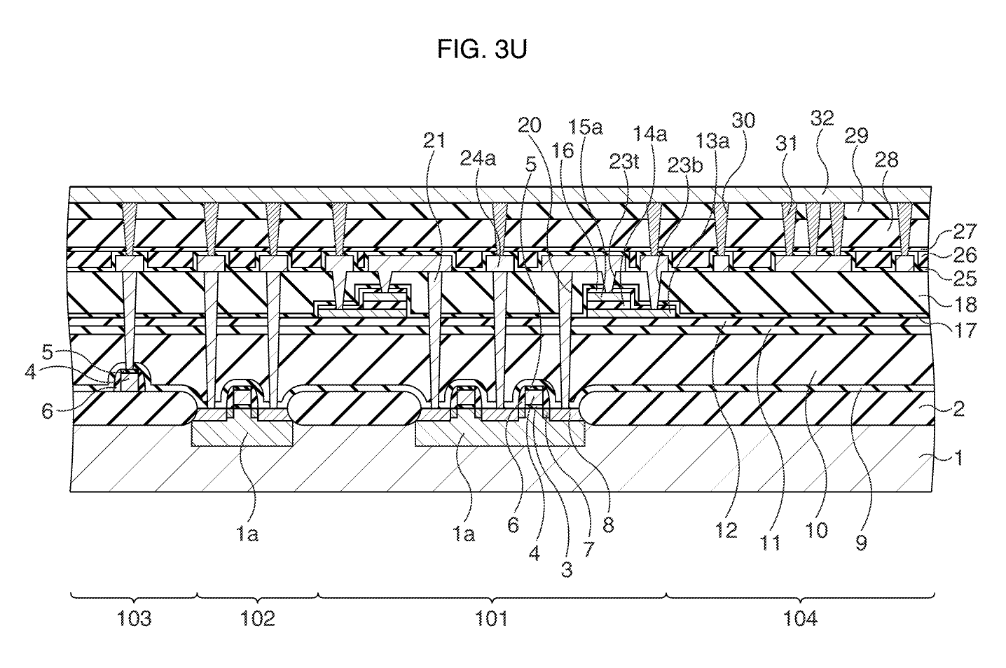

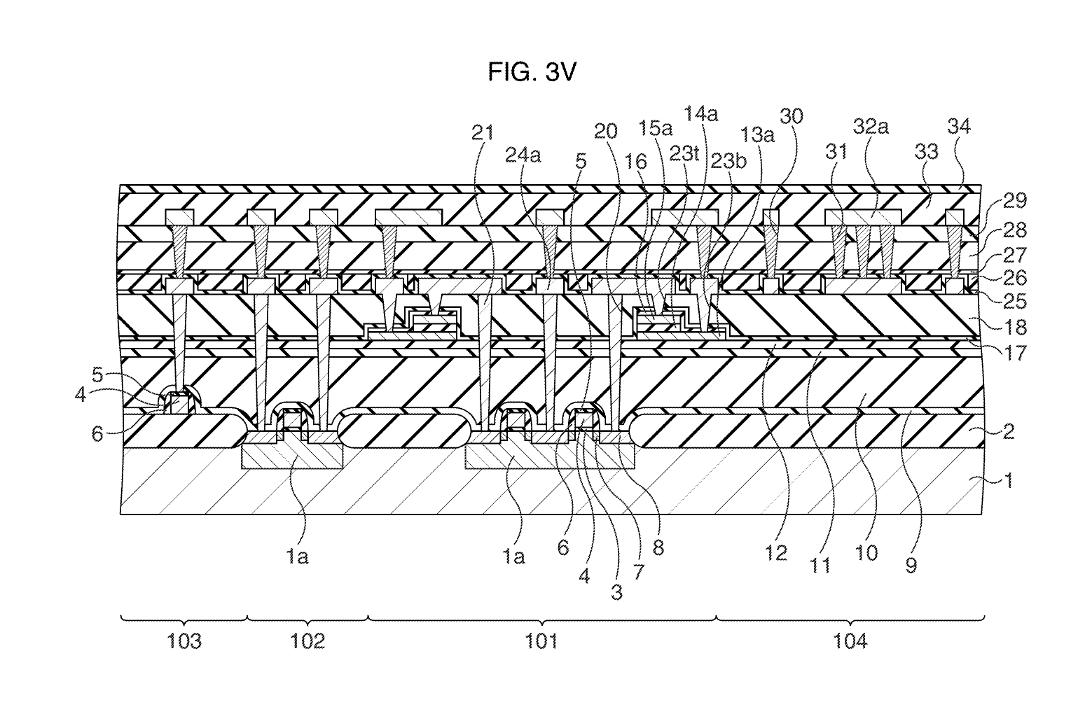

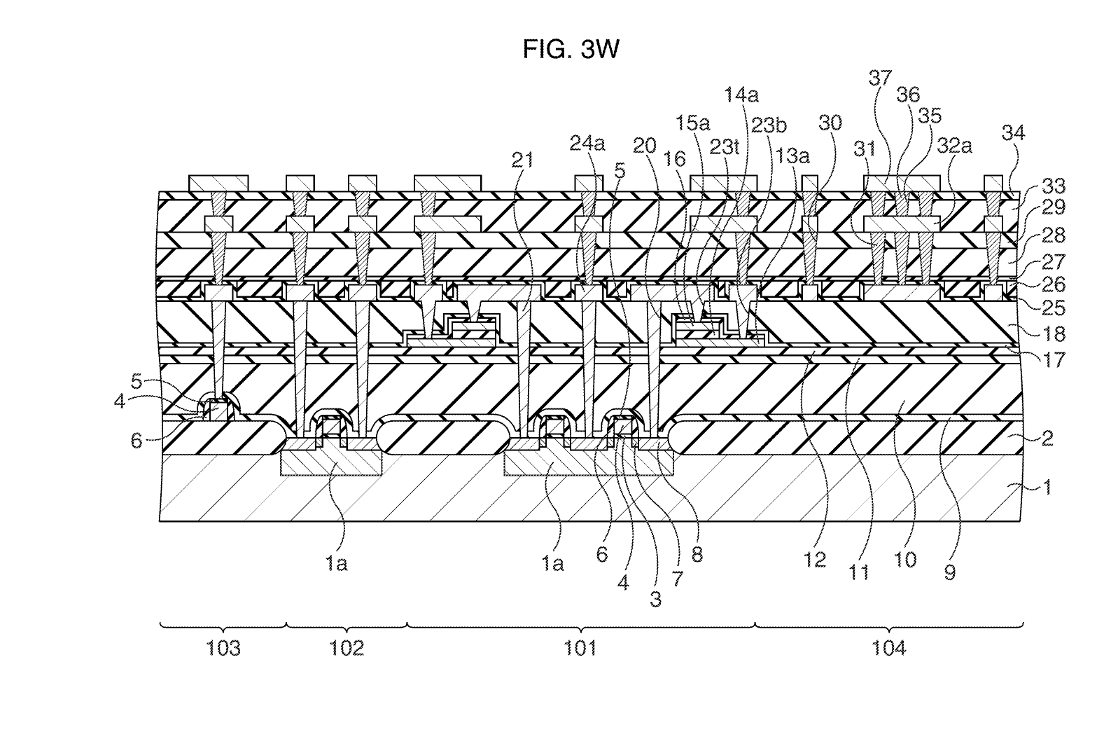

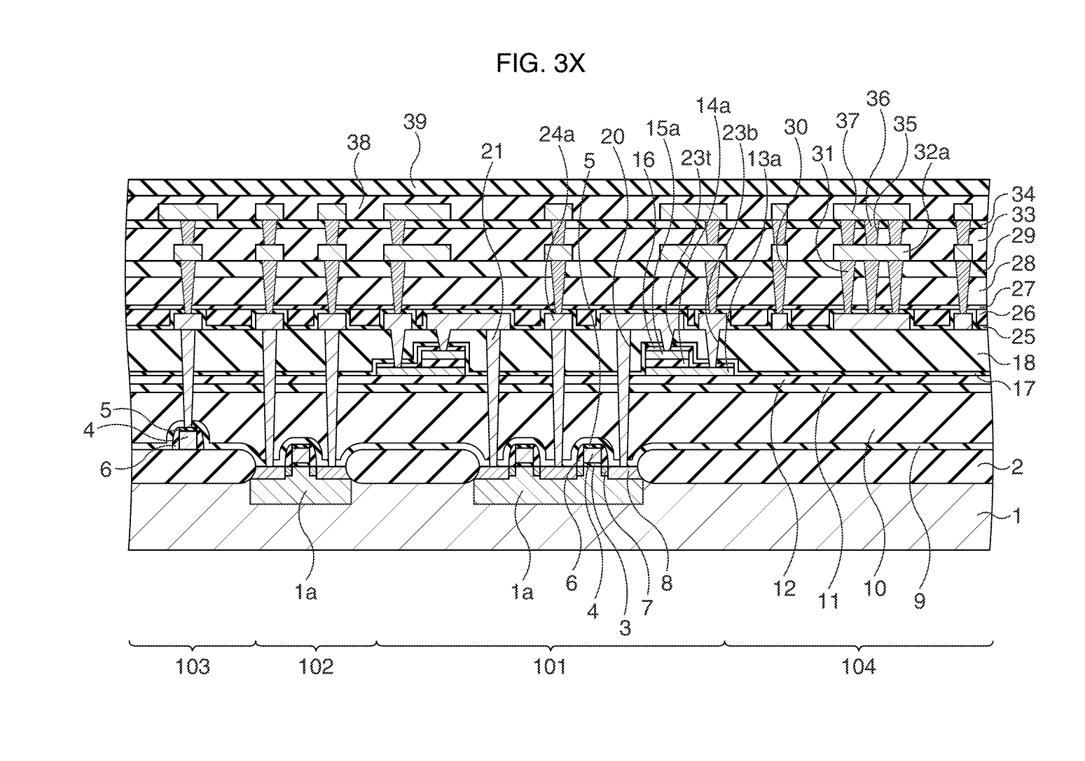

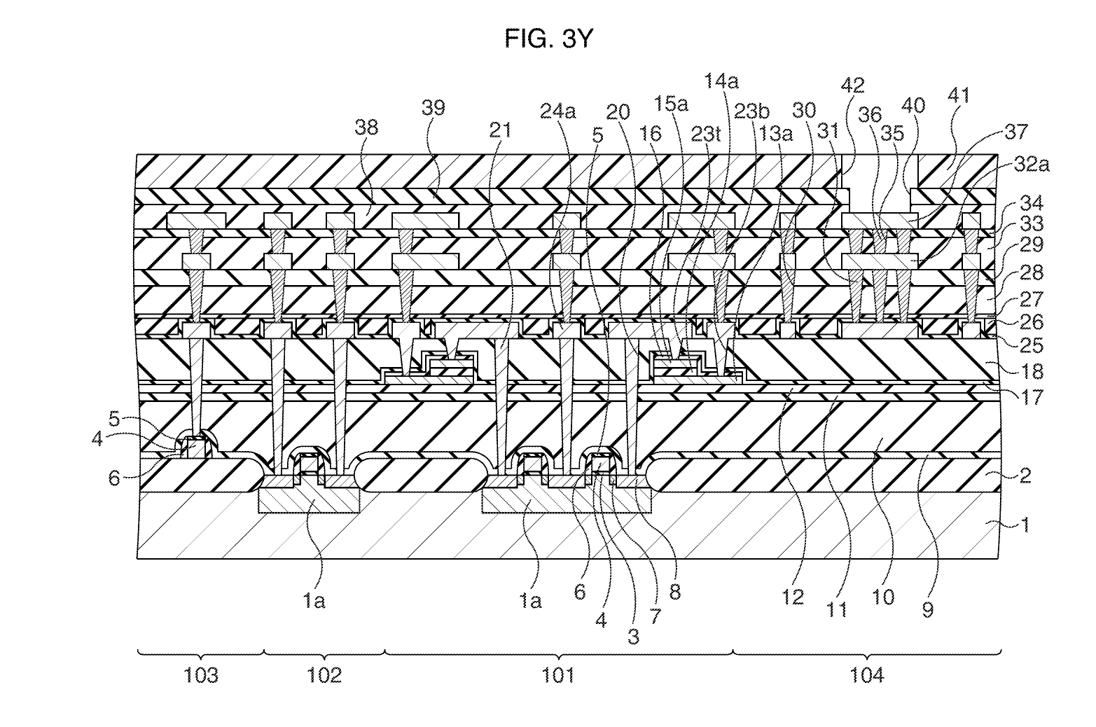

Next, a manufacturing method of the semiconductor device according to the first embodiment is described. FIG. 3A to FIG. 3Y are sectional views showing the manufacturing method of the ferroelectric memory (semiconductor device) according to the first embodiment in process sequence.

First, as shown in FIG. 3A, the element isolation regions 2 defining the element regions are formed on the surface of the semiconductor substrate 1 such as a silicon substrate. Next, the wells 1a are formed in the element regions defined by the element isolation regions 2. Next, the transistor including the gate insulating film 3, the gate electrode 4, the cap insulating film 5, the sidewall insulating film 6, the low-concentration diffusion layers 7 and the high-concentration diffusion layers 8 is formed on the well 1a. At this time, a thickness of the gate insulating film 3 is, for example, approximately 6 nm to 7 nm. A structure of the gate electrode 4 is a polycide structure composed of, for example, a poly-silicon film of which thickness is approximately 50 nm, and a metal silicide film such as a tungsten silicide film of which thickness is approximately 150 nm formed thereon. As the cap insulating film 5, a silicon oxide film of which thickness is, for example, approximately 45 nm is formed. Besides, a gate length is, for example, approximately 360 nm.

After that, as shown in FIG. 3B, the SiON film 9 covering the transistors is formed by, for example, a plasma CVD method. A thickness of the SiON film 9 is, for example, approximately 200 nm. Subsequently, the silicon oxide film (NSG film) 10 is formed on the SiON film 9 by, for example, a plasma CVD method in which source gas is TEOS. A thickness of the silicon oxide film 10 is, for example, 600 nm. Next, the surface of the silicon oxide film 10 is flattened by polishing for approximately 200 nm by, for example, a CMP method.

Next, as shown in FIG. 3C, the silicon oxide film (NSG film) 11 is formed on the silicon oxide film 10 by, for example, a plasma CVD method in which source gas is TEOS. A thickness of the silicon oxide film 11 is, for example, 100 nm. After that, a heat treatment is performed for the silicon oxide film 11 at 650° C. for 30 minutes, for example, under a nitrous oxide (N₂O) or nitrogen (N₂) atmosphere. As a result of this, a dehydration treatment of the silicon oxide film 11 is performed, and a surface of the silicon oxide film 11 is a little nitride. During the heat treatment, nitrogen is supplied with a flow rate of 20 liter/minute, for example.

Subsequently, the barrier film 12 is formed on the silicon oxide film 11. As the barrier film 12, an aluminum oxide film with a thickness of, for example, approximately 20 nm is formed by a PVD method. Next, a heat treatment (annealing) is performed by, for example, an RTA method at 650° C. for 60 seconds. During the heat treatment, oxygen is supplied with the flow rate of 2 liter/minute, for example.

Next, as shown in FIG. 3D, a bottom electrode film 13 is formed on the barrier film 12. As the bottom electrode film 13, a Pt film with a thickness of, for example, approximately 155 nm is formed by a PVD method. After that, a ferroelectric film 14 is formed on the bottom electrode film 13. As the ferroelectric film 14, a PZT film with a thickness of, for example, approximately 150 nm to 200 nm is formed by a PVD method. Subsequently, a heat treatment (annealing) is performed by, for example, a RTA method at 585° C. for 90 seconds. During the heat treatment, oxygen is supplied with the flow rate of 0.025 liter/minute, for example.

Next, a top electrode film 15 is formed on the ferroelectric film 14. When the top electrode film 15 is formed, an IrO_{X} film is formed by, for example, a PVD method, and thereafter, an IrO_{Y} film is formed on the IrO_{X} film by, for example, a PVD method. Thicknesses of the IrO_{X} film and the IrO_{Y} film are, for example, approximately 50 nm and approximately 200 nm respectively. Note that, a heat treatment (annealing) is performed by, for example, a RTA method at 725° C. for 20 seconds, between the formation of the IrO_{X} film and the formation of the IrO_{Y} film. During the heat treatment, oxygen is supplied with the flow rate of 0.025 liter/minute, for example.

Next, as shown in FIG. 3E, the top electrode film 15 is patterned with a resist pattern (not shown), and thereby, the top electrodes 15a are formed. After that, recovery annealing is performed for the ferroelectric film 14 at 650° C. for 60 minutes. During the recovery annealing, oxygen is supplied to a vertical furnace with the flow rate of 20 liter/minute, for example.

Subsequently, the ferroelectric film 14 is patterned with another resist pattern (not shown), and thereby, a capacitor insulating film is formed. In the present description, this capacitor insulating film is represented as the ferroelectric film 14a. Next, recovery annealing is performed for the ferroelectric film 14a at 350° C. for 60 minutes. During the recovery annealing, oxygen is supplied to a vertical furnace with the flow rate of 20 liter/minute, for example.

Next, as shown in FIG. 3F, the barrier film 16 covering the upper surface and side surfaces of the top electrode 15a and the ferroelectric film 14a is formed. As the barrier film 16, an aluminum oxide film with a thickness of, for example, approximately 50 nm is formed by a PVD method. After that, recovery annealing is performed at 550° C. for 60 minutes in a vertical furnace, for example. During the recovery annealing, oxygen is supplied with the flow rate of 20 liter/minute, for example.

Subsequently, as shown in FIG. 3G, the bottom electrode film 13 and the barrier film 16 are patterned with still another resist pattern (not shown), and thereby the bottom electrodes 13a are formed. The ferroelectric capacitor is composed of the bottom electrode 13a, the ferroelectric film 14a and the top electrode 15a. Next, recovery annealing is performed at 650° C. for 60 minutes in a vertical furnace, for example. During the recovery annealing, oxygen is supplied with the flow rate of 20 liter/minute, for example. Next, the barrier film 17 covering the ferroelectric capacitor and the barrier film 16 is formed. As the barrier film 17, an aluminum oxide film with a thickness of, for example, approximately 20 nm is formed by a PVD method. After that, recovery annealing is performed at 550° C. for 60 minutes in a vertical furnace, for example. During the recovery annealing, oxygen is supplied with the flow rate of 20 liter/minute, for example.

Subsequently, as shown in FIG. 3H, the interlayer insulating film 18 completely covering the ferroelectric capacitor and the barrier film 17 is formed. As the interlayer insulating film 18, a silicon oxide film (NSG film) is formed by, for example, a plasma CVD method in which source gas is TEOS. A thickness of the interlayer insulating film 18 is, for example, 1500 nm. Next, the surface of the interlayer insulating film 18 is flattened by polishing by a CMP method, for example. Next, plasma annealing using an N₂O plasma is performed in a CVD apparatus, for example, and thereby, the surface of the interlayer insulating film 18 is nitride. The plasma annealing is performed, at 350° C. for 2 minutes for example.

After that, as shown in FIG. 3I, the interlayer insulating film 18, the barrier film 17, the barrier film 12, the silicon oxide film 11, the silicon oxide film 10 and the SiON film 9 are patterned with a resist mask 19 in which a predetermined pattern is formed, and thereby, the contact holes 20 reaching the high-concentration diffusion layers 8 are formed.

Subsequently, the Ti film with a thickness of approximately 20 nm and the TiN film with a thickness of approximately 50 nm are sequentially formed as the barrier metal film (not shown) by a PVD method, for example, for the whole surface. Next, a tungsten film with a thickness of approximately 500 nm is formed by a CVD method, for example, for the whole surface. Next, the tungsten film, the TiN film and the Ti film are polished by a CMP method, for example, until the interlayer insulating film 18 is exposed. As a result of this, the tungsten film remains in the contact hole 20, and the conductive plug 21 is composed of the tungsten film as shown in FIG. 3J. After that, plasma annealing using N₂O plasma is performed in a CVD apparatus, for example, and thereby, the surface of the interlayer insulating film 18 is nitride. This plasma annealing is performed at 350° C. for 2 minutes, for example. Subsequently, a SiON film 22 with a thickness of approximately 100 nm is formed on the interlayer insulating film 18 by a plasma CVD method, for example.

Next, as shown in FIG. 3K, the SiON film 22, the interlayer insulating film 18, the barrier film 17 and the barrier film 12 are patterned with a resist mask (not shown) in which a predetermined pattern is formed, and thereby, the contact holes 23t reaching the top electrodes 15a and the contact holes 23b reaching the bottom electrodes 13a are formed. Next, recovery annealing is performed at 500° C. for 60 minutes in a vertical furnace, for example. During the recovery annealing, oxygen is supplied with the flow rate of 20 liter/minute, for example.

After that, as shown in FIG. 3L, the SiON film 22 is removed by etching (etched back).

Subsequently, as shown in FIG. 3M, a conductive film 24 is formed by a PVD method, for example. When the conductive film 24 is formed, for example, a TiN film with a thickness of 150 nm, an AlCu alloy film with a thickness of 550 nm, a Ti film with a thickness of 5 nm and the TiN film with a thickness of 150 nm are sequentially formed.

Next, as shown in FIG. 3N, the conductive film 24 is patterned with a resist mask (not shown) in which a predetermined pattern is formed, and thereby, the wirings 24a are formed. Next, a heat treatment (annealing) is performed at 350° C. for 30 minutes in a vertical furnace, for example. During the heat treatment, oxygen is supplied with the flow rate of 20 liter/minute, for example.

After that, as shown in FIG. 3O, the barrier film 25 covering the wirings 24a is formed. As the barrier film 25, an aluminum oxide film with a thickness of, for example, approximately 20 nm is formed by a PVD method.

Subsequently, as shown in FIG. 3P, the silicon oxide film 26 embedding gaps between the adjacent wirings 24a is formed. As the silicon oxide film 26, a NSG film is formed by a plasma CVD method in which source gas is TEOS, for example.

Next, as shown in FIG. 3Q, the silicon oxide film 26 is polished by a CMP method, for example, until a surface of the barrier film 25 is exposed. After that, plasma annealing is performed with N₂O plasma in a CVD apparatus, for example, and thereby, a surface of the silicon oxide film 26 is nitride. The plasma annealing is performed, for example, at 350° C. for 4 minutes. In this plasma annealing, dehydration treatment of the silicon oxide film 26 is also performed.

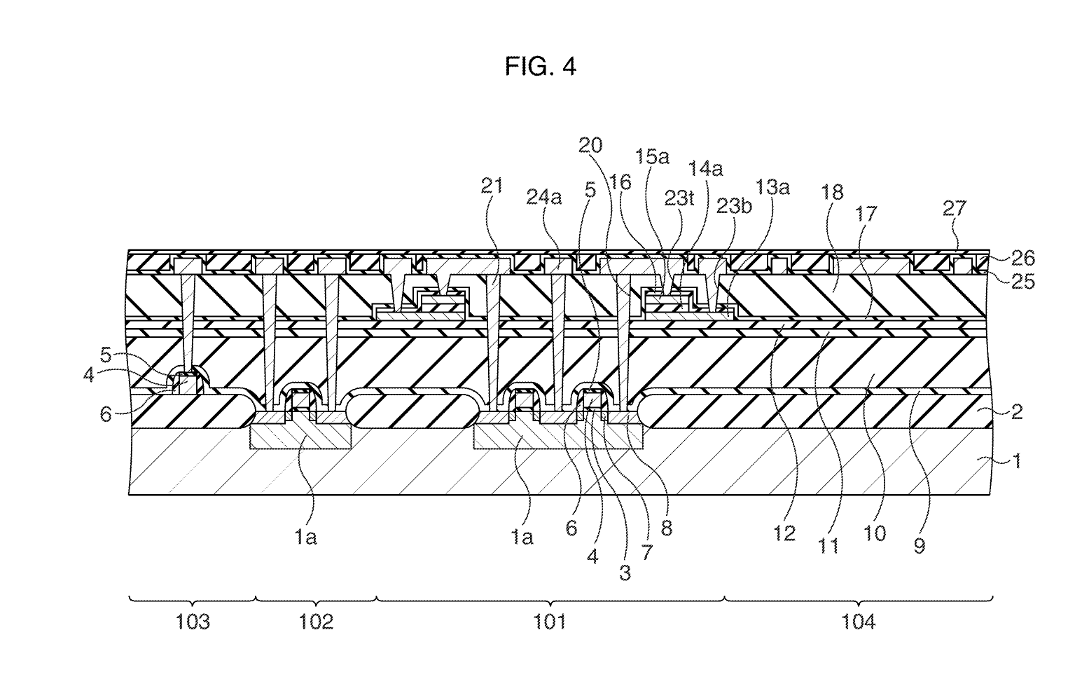

Next, as shown in FIG. 3R and FIG. 4, the barrier film 27 is formed on the barrier film 25 and the silicon oxide film 26. As the barrier film 27, an aluminum oxide film with a thickness of, for example, approximately 50 nm is formed by a PVD method.

After that, as shown in FIG. 3S, the silicon oxide film 28 is formed on the barrier film 27. As the silicon oxide film 28, a NSG film is formed by a plasma CVD method in which source gas is TEOS, for example. Besides, a thickness of the silicon oxide film 28 is, for example, approximately 2600 nm. Subsequently, plasma annealing is performed with N₂O plasma in a CVD apparatus, for example, and thereby, a surface of the silicon oxide film 28 is nitride. The plasma annealing is performed at 350° C. for 4 minutes, for example. In the plasma annealing, dehydration treatment of the silicon oxide film 28 is also performed.

Next, the silicon oxide film 29 is formed on the silicon oxide film 28. As the silicon oxide film 29, a NSG film is formed by a plasma CVD method in which source gas is TEOS, for example. Besides, a thickness of the silicon oxide film 29 is, for example, approximately 100 nm. Next, plasma annealing is performed with N₂O plasma in a CVD apparatus, for example, and thereby, the surface of the silicon oxide film 29 is nitride. The plasma annealing is performed at 350° C. for 2 minutes, for example. In the plasma annealing, dehydration treatment of the silicon oxide film 29 is also performed.

After that, as shown in FIG. 3T, the silicon oxide film 29, the silicon oxide film 28, the barrier film 27 and the barrier film 25 are patterned with a resist mask (not shown) in which a predetermined pattern is formed, and thereby, the contact holes 30 reaching the wirings 24a are formed.

Subsequently, a TiN film with a thickness of approximately 50 nm is formed as a barrier metal film (not shown) by a PVD method, for example, for the whole surface. Next, a tungsten film with a thickness of approximately 650 nm is formed by a CVD method, for example, for the whole surface. Next, the tungsten film and the TiN film are polished by a CMP method, for example, until the silicon oxide film 29 is exposed. As a result of this, the tungsten film remains in the contact hole 30, and the conductive plugs 31 are composed of this tungsten film as shown in FIG. 3U. After that, a conductive film 32 is formed by a PVD method, for example. When the conductive film 32 is formed, for example, an AlCu alloy film with a thickness of 550 nm, a Ti film with a thickness of 5 nm and a TiN film with a thickness of 150 nm are sequentially formed.

Subsequently, as shown in FIG. 3V, the conductive film 32 is patterned with a resist mask (not shown) in which a predetermined pattern is formed, and thereby, the wirings 32a are formed. Next, the silicon oxide film 33 covering the wirings 32a is formed. As the silicon oxide film 33, a NSG film is formed by a plasma CVD method in which source gas is TEOS, for example. Besides, a thickness of the silicon oxide film 33 is, for example, approximately 2200 nm. Next, the surface of the silicon oxide film 33 is polished by a CMP method, for example, and thereby, it is flattened. After that, plasma annealing is performed with N₂O plasma in a CVD apparatus, for example, and thereby, the surface of the silicon oxide film 33 is nitride. The plasma annealing is performed at 350° C. for 4 minutes, for example.

Subsequently, the silicon oxide film 34 with a thickness of, for example, approximately 100 nm is formed on the silicon oxide film 33. As the silicon oxide film 34, a NSG film is formed by a plasma CVD method in which source gas is TEOS, for example. Next, plasma annealing is performed with N₂O plasma in a CVD apparatus, for example, and thereby, a surface of the silicon oxide film 34 is nitride. The plasma annealing is performed at 350° C. for 2 minutes, for example.

Next, as shown in FIG. 3W, the silicon oxide films 34 and 33 are patterned with a resist mask (not shown) in which a predetermined pattern is formed, and thereby, the contact holes 35 reaching the wirings 32a are formed. After that, the TiN film with a thickness of approximately 50 nm is formed as a barrier metal film (not shown) for the whole surface by a PVD method, for example. Subsequently, a tungsten film with a thickness of approximately 650 nm is formed for the whole surface by a CVD method, for example. Next, the tungsten film and the TiN film are polished by a CMP method, for example, until the silicon oxide film 34 is exposed. As a result of this, the tungsten films remain in the contact holes 35, and the conductive plugs 36 are composed of these tungsten films. Subsequently, the wirings 37 are formed by a PVD method, for example. When the wirings 37 are formed, for example, an AlCu alloy film with a thickness of 500 nm and a TiN film with a thickness of 150 nm are sequentially formed, and these films are patterned.

After that, as shown in FIG. 3X, the silicon oxide film 38 covering the wirings 37 is formed. As the silicon oxide film 38, a NSG film is formed by a plasma CVD method in which source gas is TEOS, for example. A thickness of the silicon oxide film 38 is, for example, approximately 100 nm. Subsequently, plasma annealing is performed with N₂O plasma in a CVD apparatus, for example, and thereby, a surface of the silicon oxide film 38 is nitride. The plasma annealing is performed at 350° C. for 2 minutes, for example.

Next, the silicon nitride film 39 with a thickness of approximately 350 nm is formed on the silicon oxide film 38 by a plasma CVD method, for example. The silicon oxide film 38 and the silicon nitride film 39 function as a passivation film.

Next, as shown in FIG. 3Y, the silicon nitride film 39 and the silicon oxide film 38 are patterned with a resist mask (not shown) in which a predetermined pattern is formed, and thereby, the opening 40 exposing a part of the wirings 37 is formed in the pad portion 104. Incidentally, in this patterning, the TiN film constituting the wirings 37 is also removed.

After that, a photosensitive polyimide is coated, and thereby, a protective film 41 with a thickness of approximately 3 μm is formed on the silicon nitride film 39. Subsequently, an exposure and a development are performed for the protective film 41, and thereby, the opening 42 exposing the opening 40 is formed in the pad portion 104.

Heat treatment is performed at 310° C. for 40 minutes in a horizontal furnace, for example. During the heat treatment, nitride is supplied with the flow rate of 100 liter/minute, for example. As a result, the protective film 41 composed of the photosensitive polyimide is cured.

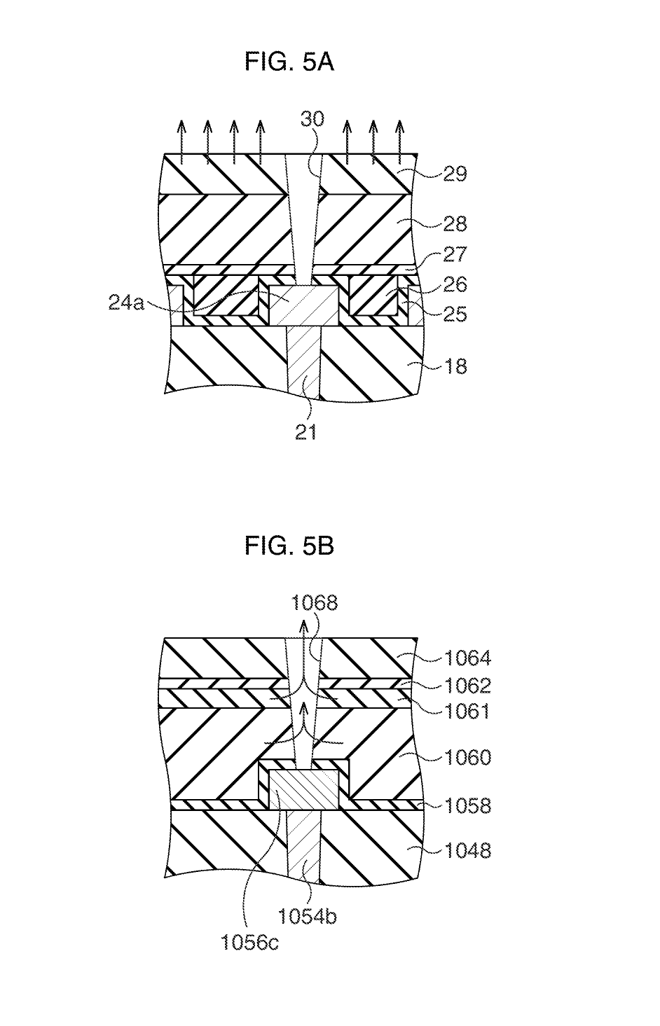

As stated above, in the reference example, the barrier film 1062 exists over the silicon oxide films 1060 and 1061, and leaving of moisture in the silicon oxide films 1060 and 1061 for upward is disturbed by the barrier film 1062, as shown in FIG. 5B. Accordingly, the moisture is leaving via the contact hole 1068, and the formations of the barrier metal film and the tungsten film are disturbed.

On the contrary, in the first embodiment, nothing exists to disturb leaving of moisture over the silicon oxide films 28 and 29 after the contact hole 30 is formed, as shown in FIG. 5A. Accordingly, almost all of the moisture in the silicon oxide films 28 and 29 leaving from the surface of the silicon oxide film 29 for outside when it is heated during the formation processes of the barrier metal film and the tungsten film. Namely, the moisture leaving via the contact holes 30 is extremely little.

Consequently, the fine barrier metal film and tungsten film are formed, and the properties become stable.

### Second Embodiment

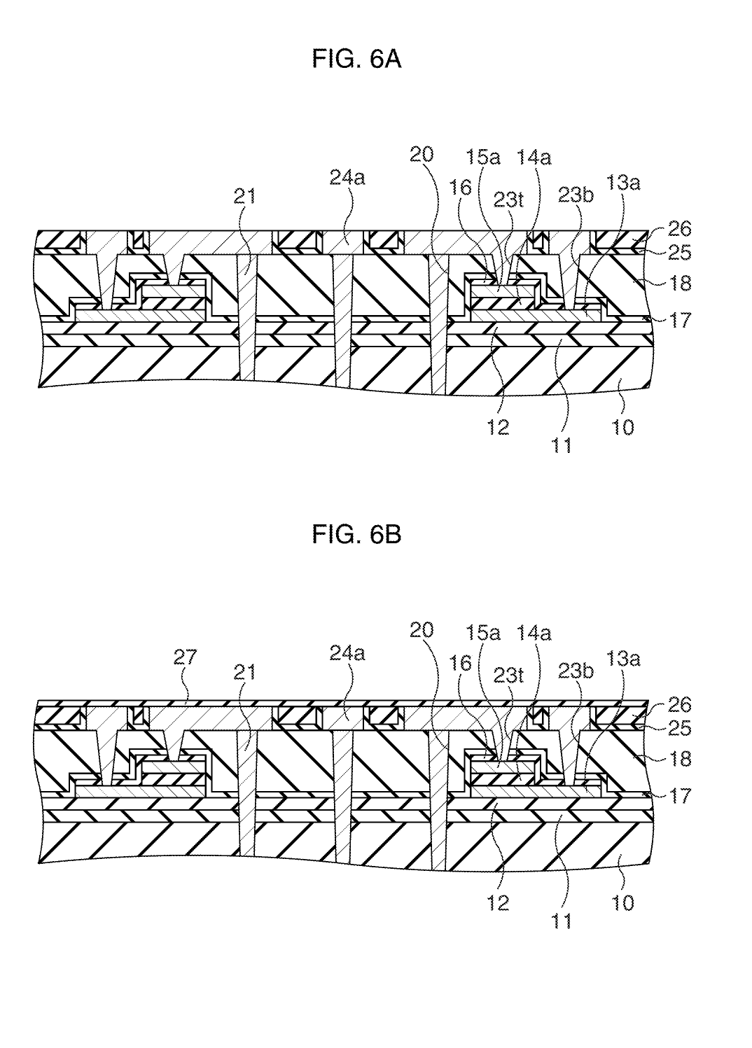

Next, a second embodiment is described. FIG. 6A to FIG. 6B are sectional views showing a manufacturing method of a ferroelectric memory (semiconductor device) according to the second embodiment in process sequence.

In manufacturing the ferroelectric memory according to the second embodiment, first, the processes until forming the silicon oxide film 26 are performed as same as the first embodiment, as shown in FIG. 3P.

Next, as shown in FIG. 6A, the silicon oxide film 26 and the barrier film 25 are polished until the surfaces of the wirings 24a are exposed by a CMP method, for example. After that, plasma annealing with N₂O plasma is performed in a CVD apparatus, for example, and thereby, the surface of the silicon oxide film 26 is nitride. The plasma annealing is performed at 350° C. for 4 minutes, for example. In this plasma annealing, dehydration treatment of the silicon oxide film 26 is also performed.

Next, as shown in FIG. 6B, the barrier film 27 is formed on the wirings 24a, the barrier film 25 and the silicon oxide film 26. As the barrier film 27, an aluminum oxide film with a thickness of, for example, approximately 50 nm is formed by a PVD method.

After that, the processes from forming the silicon oxide film 28 are performed as same as the first embodiment.

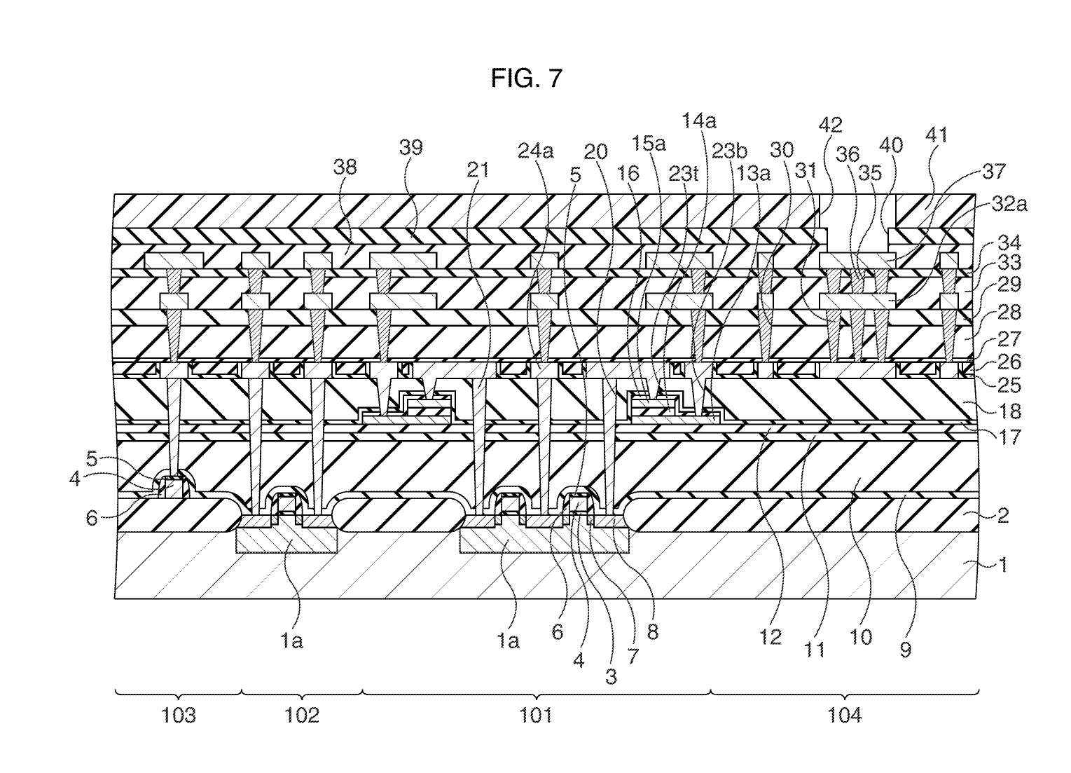

According to the second embodiment as described above, as shown in FIG. 7, the similar structure to the first embodiment can be obtained except that the barrier film 27 is directly in contact with the surface of the wirings 24a without being intervened by the barrier film 25.

Consequently, it is possible that the moisture leaves from the surface of the silicon oxide film 29 after the formation of the contact holes 30 as same as the first embodiment. Accordingly, the effect similar to the first embodiment can be obtained.

### Third Embodiment

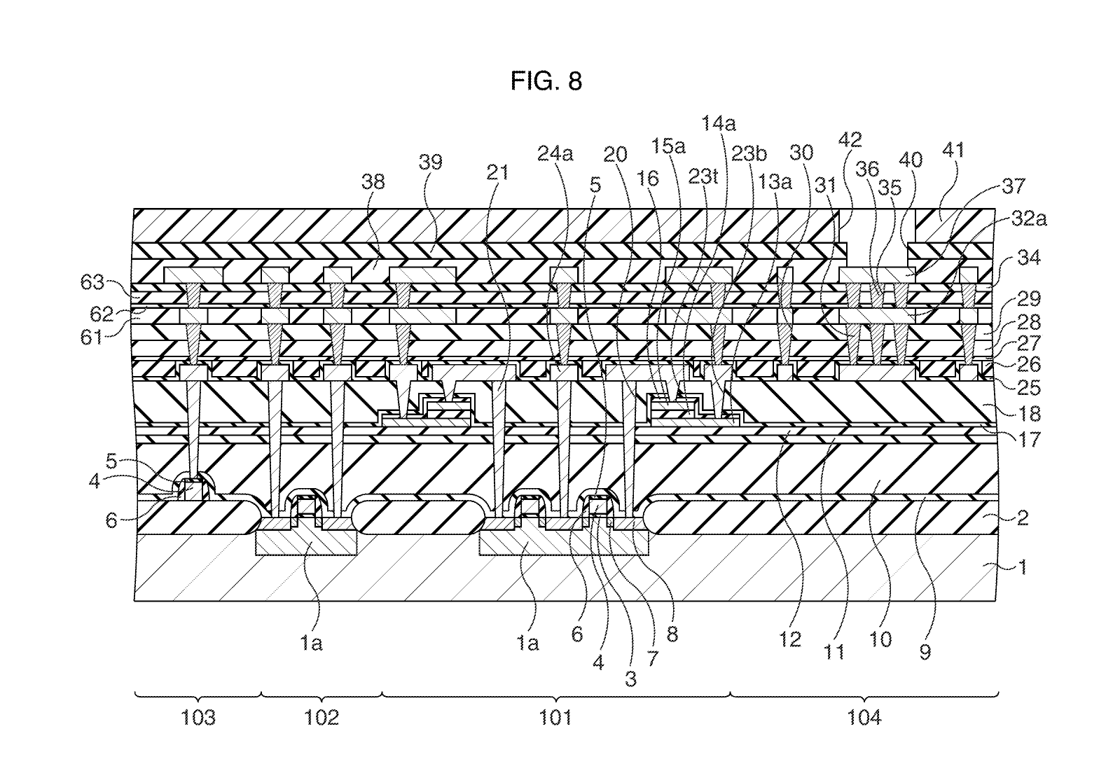

Next, a third embodiment is described. FIG. 8 is a sectional view showing a ferroelectric memory (semiconductor device) according to the third embodiment.

In the present embodiment, a silicon oxide film 61 is formed between the adjacent wirings 32a. A barrier film 62 is formed on the silicon oxide film 61 and the wirings 32a. A silicon oxide film 63 is formed on the barrier film 62. Namely, the silicon oxide film 61, the barrier film 62 and the silicon oxide film 63 are formed instead of the silicon oxide film 33 in the first embodiment.

In manufacturing the ferroelectric memory according to the third embodiment as described above, first, the processes until forming the wirings 32a are performed as same as the first embodiment. Next, the silicon oxide film 61 covering the wirings 32a is formed, and it is flattened by a CMP method, for example, until the wirings 32a are exposed. As the silicon oxide film 61, a NSG film is formed by a plasma CVD method in which source gas is TEOS for example. After that, plasma annealing is performed with N₂O plasma in a CVD apparatus, for example, and thereby, a surface of the silicon oxide film 61 is nitride. Next, the barrier film 62 is formed on the silicon oxide film 61 and the wirings 32a. As the barrier film 62, an aluminum oxide film is formed by a PVD method, for example. Subsequently, the silicon oxide film 63 is formed on the barrier film 62, and it is flattened. As the silicon oxide film 63, a NSG film is formed by a plasma CVD method in which source gas is TEOS, for example. After that, plasma annealing is performed with N₂O plasma in a CVD apparatus, for example, and thereby, a surface of the silicon oxide film 63 is nitride.

The processes from forming the silicon oxide film 34 are then performed as same as the first embodiment.

In the third embodiment as described above, the flat barrier film 62 is added, and therefore, it is possible to prevent the penetration of moisture more surely compared to the first embodiment. Besides, the barrier film 62 is in contact with the surfaces of the wirings 32a, and therefore, when the conductive plugs 36 are formed, it is possible that the moisture in the silicon oxide films 63 and 34 leaves from the surface of the silicon oxide film 34. Consequently, the formation of the conductive plugs 36 is not disturbed.

### Fourth Embodiment

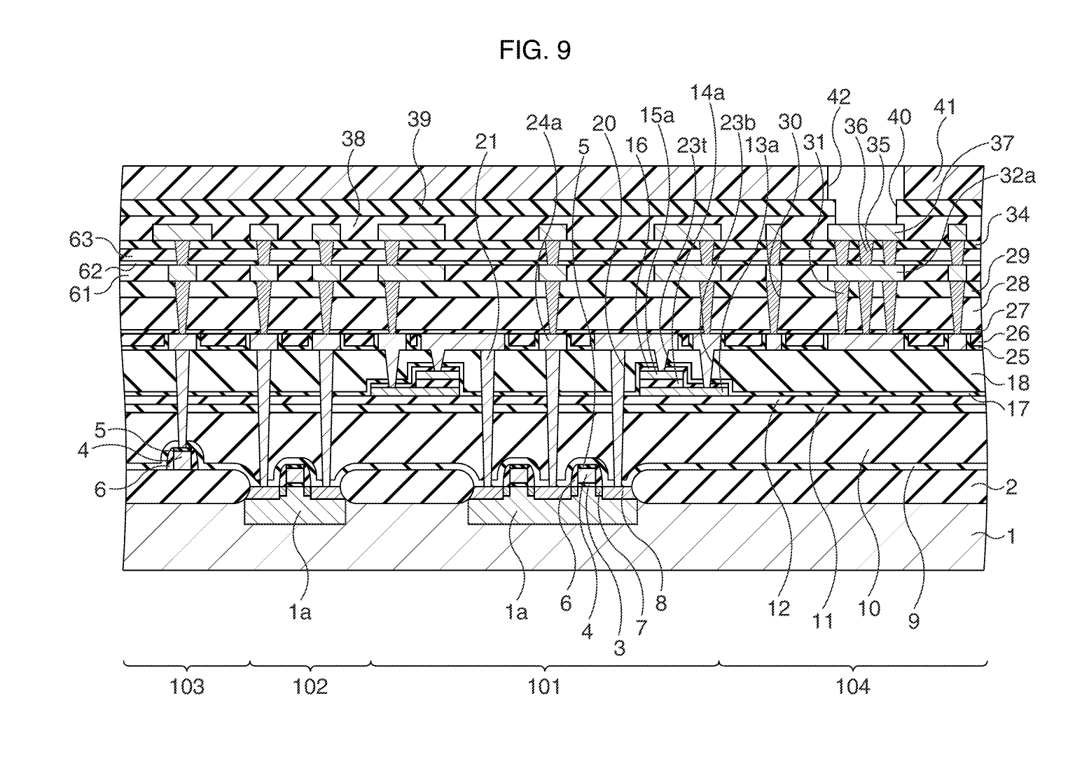

Next, a fourth embodiment is described. FIG. 9 is a sectional view showing a ferroelectric memory (semiconductor device) according to the fourth embodiment.

In the fourth embodiment, the silicon oxide film 61, the barrier film 62 and the silicon oxide film 63 are formed instead of the silicon oxide film 33 in the second embodiment. Consequently, the effect of the third embodiment together with the effect of the second embodiment can be obtained.

Incidentally, in the present embodiment, the barrier film is not limited to the aluminum oxide film, but it may be a film capable of preventing the diffusion of at least hydrogen or moisture, such as a metal oxide film or a metal nitride film. For example, a titanium oxide film, an Al nitride film, an Al oxynitride film, a Ta oxide film, a Ta nitride film and a Zr oxide film, a Si oxynitride film and the like may be used. The metal oxide film is minute, and therefore, it is possible to surely prevent the diffusion of hydrogen even if the film is relatively thin. Consequently, it is preferable that the metal oxide is used as the barrier film from a view of miniaturization.

Besides, a crystal structure of substances composing the ferroelectric film is not limited to the perovskite type structure, but it may be, for example, a Bi-layer structure. Besides, a composition of substances composing the ferroelectric film is not limited in particular. For example, Pb (lead), Sr (strontium), Ca (calcium), Bi (bismuth), Ba (barium), Li (lithium) and/or Y (yttrium) may be contained as an acceptor element, and Ti (titanium), Zr (zirconium), Hf (hafnium), V (vanadium), Ta (tantalum), W (tungsten), Mn (manganese), Al (aluminum), Bi (bismuth) and/or Sr (strontium) may be contained as a donor element.

For example, Pb(Zr, Ti)O₃, (Pb, Ca)(Zr, Ti)O₃, (Pb, Ca)(Zr, Ti, Ta)O₃, (Pb, Ca)(Zr, Ti, W)O₃, (Pb, Sr)(Zr, Ti)O₃, (Pb, Sr)(Zr, Ti, W)O₃, (Pb, Sr)(Zr, Ti, Ta)O₃, (Pb, Ca, Sr)(Zr, Ti)O₃, (Pb, Ca, Sr)(Zr, Ti, W)O₃, (Pb, Ca, Sr)(Zr, Ti, Ta) O₃, SrBi₂ (Ta_{X}Nb_{1-X})₂O₉, SrBi₂Ta₂O₉, Bi₄Ti₂O₁₂, Bi₄Ti₃O₉, and BaBi₂Ta₂O₉ are cited as a chemical formula of the substances composing the ferroelectric film, but it is not limited to the above. Besides, Si may be added to the above.

Besides, the present embodiment is not limited to be applied to the ferroelectric memory, but it may be applied to, for example, a DRAM and so on. When it is applied to the DRAM, a high dielectric constant film, for example, such as a (BaSr)TiO₃ film (BST film), an SrTiO₃ film (STO film), a Ta₂O₅ film may be used instead of the ferroelectric film. Incidentally, the high dielectric constant film means a dielectric constant film of which relative dielectric constant is higher than a silicon dioxide.

Besides, compositions of the top electrode and the bottom electrode are not limited in particular. The bottom electrode may be composed of, for example, Pt (platinum), Ir (iridium), Ru (ruthenium), Rh (rhodium), Re (rhenium), Os (osmium) and/or Pd (palladium), or it may be composed of an oxide of the above. Layers lower than a noble metal cap film of the top electrode may be composed of, for example, the oxide of Pt, Ir, Ru, Rh, Re, Os and/or Pd. Besides, the top electrode may be constituted by stacking plural films.

Further, a structure of the ferroelectric memory cell is not limited to the 1T1C-type, but it may be a 2T2C-type. Besides, the ferroelectric memory may have a constitution in which the ferroelectric capacitor in itself is used as both a storage portion and a switching portion. In this case, the structure may become the one in which the ferroelectric capacitor is formed instead of a gate electrode of a MOS transistor. Namely, the ferroelectric capacitor is formed on a semiconductor substrate via a gate insulating film.

Besides, a forming method of the ferroelectric film is not limited in particular. For example, a sol-gel method, a metallo-organic decomposition (MOD) method, a CSD (Chemical Solution Deposition) method, a chemical vapor deposition (CVD) method, an epitaxial growth method, a sputtering method, a MOCVD (Metal Organic Chemical Vapor Deposition) method, and the like may be adopted.

Besides, in the above-stated embodiments, a structure of the ferroelectric capacitor is a planar structure, but a ferroelectric capacitor having a stack structure may be used.

### INDUSTRIAL APPLICABILITY

As stated above, according to the present embodiment, a barrier layer of which surface is flat is formed, and therefore, a high barrier property can be obtained. Besides, since the barrier layer directly covers first wirings, this barrier layer does not disturb leaving of moisture in an interlayer insulating film positioning between second wirings and the first wirings. Consequently, it is possible to keep an electrical connection between the first wirings and the second wirings in a good state. Further, in a case where a barrier film (a third barrier film) is provided on the second wirings, even if some defects occur at both of the barrier layer and the barrier film, defected positions may be displaced from one another in most cases. Accordingly, it is possible to prevent penetration of hydrogen and moisture by at least one of them. Namely, it is possible to secure the barrier property more surely.

What is claimed is:

1. A manufacturing method of a semiconductor device, comprising:
forming a ferroelectric capacitor including a bottom electrode, a ferroelectric film and a top electrode above a semiconductor substrate;
forming a first interlayer insulating film over said ferroelectric capacitor;
forming a first conductive plug in said first interlayer insulating film;
forming a first wiring over said first interlayer insulating film, said first conductive plug being connected to said first wiring and to one of said top electrode and bottom electrode;
forming a barrier layer, a surface of which is flat, directly on said first wiring and covering the first wiring, and preventing diffusion of hydrogen or moisture;
forming a second interlayer insulating film over the barrier layer; and
forming a second wiring, a part of which is connected to the first wiring, over the second interlayer insulating film,
wherein said forming the barrier layer includes:
forming a first barrier film covering a side surface and an upper surface of the first wiring;
forming an insulating film over the first barrier film;
polishing the insulating film to flatten the insulating film; and
forming a flat second barrier film over the insulating film, the first barrier film being positioned between the first interlayer insulating film and the second barrier film, and the second barrier film being positioned between the first barrier film and the second interlayer insulating film.

2. The manufacturing method of a semiconductor device according to claim 1, further comprising, between said forming the first barrier film and said forming the second barrier film:
forming an insulating film on the first barrier film; and
flattening the insulating film until an upper surface of the first barrier film is exposed.

3. The manufacturing method of a semiconductor device according to claim 1, wherein said forming the barrier layer includes:
forming a first barrier film covering a side surface of the first wiring; and
forming a flat second barrier film covering an upper surface of the first wiring.

4. The manufacturing method of a semiconductor device according to claim 3, wherein said forming the first barrier film includes:
forming a material film of the first barrier film covering the side surface and the upper surface of the first wiring;
forming an insulating film on the material film; and
flattening the insulating film and the material film until the upper surface of the first wiring are exposed.

5. The manufacturing method of a semiconductor device according to claim 1, further comprising, between said forming the interlayer insulating film and said forming the second wiring:
forming a contact hole reaching the first wiring in the interlayer insulating film and the barrier layer; and
forming a second conductive plug inside the contact hole.

6. The manufacturing method of a semiconductor device according to claim 1, wherein a material of only silicon oxide is formed between said forming the barrier layer and said forming the second wiring.

7. The manufacturing method of a semiconductor device according to claim 1, further comprising, after said forming the second wiring, forming a third barrier film, a surface of which is flat, directly covering the second wiring, and preventing the diffusion of hydrogen or moisture.

8. The manufacturing method of a semiconductor device according to claim 1, wherein metal oxide films are formed as the first and second barrier films respectively.

9. The manufacturing method of a semiconductor device according to claim 3, wherein metal oxide films are formed as the first and second barrier films respectively.

10. The manufacturing method of a semiconductor device according to claim 1, wherein the insulating film is a silicon oxide film.

11. The manufacturing method of a semiconductor device according to claim 1, wherein the first barrier film is exposed by said polishing.

12. The manufacturing method of a semiconductor device according to claim 1, wherein said forming the barrier layer includes performing plasma annealing after said polishing.
